(19) United States
(12) Patent Application Publication
(10) Pub. No.: US 2026/0173627 A1
(43) Pub. Date: Jun. 18, 2026

(54) LIGHT EMITTING ELEMENT, DISPLAY DEVICE, AND ELECTRONIC APPARATUS

(71) Applicant: SONY SEMICONDUCTOR SOLUTIONS CORPORATION, KANAGAWA (JP)

(72) Inventor: TOKIHIRO YOKONO, KANAGAWA (JP)

(21) Appl. No.: 18/711,301

(22) PCT Filed: Nov. 10, 2022
(86) PCT No.: PCT/JP2022/041846

§ 371 Date: May 17, 2024

(30) Foreign Application Priority Data
Nov. 26, 2021 (JP) 2021-192029

(51) Int. Cl. H10H 29/855

(52) U.S. Cl. CPC H10H 29/855

(57) ABSTRACT

A light emitting element (PX) according to an aspect of the present disclosure includes a light emitting unit (ELP) that emits light from a light emitting surface, and a diffraction layer (for example, a protective layer (60) and extending portions (71)) that is provided on the light emitting surface side of the light emitting unit (ELP) and through which light emitted from the light emitting surface passes, and the diffraction layer (for example, the protective layer (60) and the extending portions (71)) is formed by arranging multiple materials having different refractive indexes and having optical transparency along the light emitting surface.

### FIELD

The present disclosure relates to a light emitting element, a display device, and an electronic apparatus.

### BACKGROUND

In recent years, a light emitting element having a current-driven light emitting unit and a display device including the light emitting element have been developed. For example, a light emitting element using an organic electroluminescence element (organic EL element) as a light emitting unit has attracted attention as a light emitting element capable of emitting high luminance light by low voltage direct current drive (see, for example, Patent Literature 1). The light emitting unit is configured, for example, by providing an organic layer including a light emitting layer and the like between an anode and a cathode.

### CITATION LIST

### Patent Literature

Patent Literature 1: JP 2019-16478 A

### SUMMARY

### Technical Problem

In order to collect light from the light emitting element as described above, an on-chip microlens (OCL) is used, but the light collection by the OCL does not necessarily increase a total amount of light. For this reason, it may be difficult to improve a light extraction efficiency even if the light is condensed by the OCL.

Therefore, the present disclosure proposes a light emitting element, a display device, and an electronic apparatus capable of improving a light extraction efficiency.

### Solution to Problem

A light emitting element according to the embodiment of the present disclosure includes: a light emitting unit that emits light from a light emitting surface; and a diffraction layer that is provided on the light emitting surface side of the light emitting unit and through which the light emitted from the light emitting surface passes, wherein the diffraction layer is formed by arranging a plurality of materials having different refractive indexes and having optical transparency along the light emitting surface.

A display device according to the embodiment of the present disclosure includes: a plurality of light emitting elements, wherein the plurality of light emitting elements each include: a light emitting unit that emits light from a light emitting surface; and a diffraction layer that is provided on the light emitting surface side of the light emitting unit and through which the light emitted from the light emitting surface passes, and the diffraction layer is formed by arranging a plurality of materials having different refractive indexes and having optical transparency along the light emitting surface.

An electronic apparatus according to the embodiment of the present disclosure includes: a display device that includes a plurality of light emitting elements, wherein the plurality of light emitting elements each include: a light emitting unit that emits light from a light emitting surface; and a diffraction layer that is provided on the light emitting surface side of the light emitting unit and through which the light emitted from the light emitting surface passes, and the diffraction layer is formed by arranging a plurality of materials having different refractive indexes and having optical transparency along the light emitting surface.

### BRIEF DESCRIPTION OF DRAWINGS

FIG. 1 is a diagram illustrating an example of a schematic configuration of a display device according to an embodiment.

FIG. 2 is a diagram illustrating an example of a schematic configuration of a light emitting element according to the embodiment.

FIG. 3 is a diagram illustrating an example of a schematic configuration of the light emitting element according to the embodiment.

FIG. 4 is a diagram illustrating an example of a schematic configuration of the light emitting element according to Example 1.

FIG. 5 is a cross-sectional diagram taken along line A1-A1 illustrated in FIG. 4.

FIG. 6 is a diagram illustrating an example of a schematic configuration of the light emitting element according to Example 2.

FIG. 7 is a cross-sectional diagram taken along line A2-A2 illustrated in FIG. 6.

FIG. 8 is a diagram illustrating an example of a schematic configuration of the light emitting element according to Example 3, and is a cross-sectional diagram taken along line A2-A2 illustrated in FIG. 6.

FIG. 9 is a diagram illustrating an example of a schematic configuration of the light emitting element according to Example 4, and is a cross-sectional diagram taken along line A2-A2 illustrated in FIG. 6.

FIG. 10 is a diagram illustrating an example of a schematic configuration of the light emitting element according to Example 5, and is a cross-sectional diagram taken along line A2-A2 illustrated in FIG. 6.

FIG. 11 is a diagram illustrating an example of a schematic configuration of the light emitting element according to Example 6, and is a cross-sectional diagram taken along line A2-A2 illustrated in FIG. 6.

FIG. 12 is a diagram illustrating an example of a schematic configuration of the light emitting element according to Example 7.

FIG. 13 is a diagram illustrating an example of a schematic configuration of the light emitting element according to Example 8.

FIG. 14 is a diagram illustrating an example of a schematic configuration of the light emitting element according to Example 9.

FIG. 15 is a diagram for describing a difference between light diffraction by a zone plate and light diffraction by a Fresnel lens.

FIG. 16 is a diagram for describing a difference between main light beam control by the OCL step pitch and main light beam control according to Example 2.

FIG. 17 is a diagram for describing a traveling direction of light passing through two media having different refractive indexes.

FIG. 18 is a diagram for describing the relationship between the light intensity and the radiation angle of the light emitting element.

FIG. 19 is a diagram for describing a manufacturing process of the display device according to the embodiment.

FIG. 20 is a diagram for describing the manufacturing process of the display device according to the embodiment.

FIG. 21 is a schematic cross-sectional diagram for describing a first example of a resonator structure.

FIG. 22 is a schematic cross-sectional diagram for describing a second example of the resonator structure.

FIG. 23 is a schematic cross-sectional diagram for describing a third example of the resonator structure.

FIG. 24 is a schematic cross-sectional diagram for describing a fourth example of the resonator structure.

FIG. 25 is a schematic cross-sectional diagram for describing a fifth example of the resonator structure.

FIG. 26 is a schematic cross-sectional diagram for describing a sixth example of the resonator structure.

FIG. 27 is a schematic cross-sectional diagram for describing a seventh example of the resonator structure.

FIG. 28 is a conceptual diagram for describing a first example of a shift structure.

FIG. 29 is a conceptual diagram for describing a second example of the shift structure.

FIG. 30 is a conceptual diagram for describing a third example of the shift structure.

FIG. 31 is a conceptual diagram for describing a fourth example of the shift structure.

FIG. 32 is a conceptual diagram for describing a fifth example of the shift structure.

FIG. 33 is a conceptual diagram for describing a sixth example of the shift structure.

FIG. 34 is a conceptual diagram for describing a seventh example of the shift structure.

FIG. 35 is a view illustrating an example of an appearance of a smartphone.

FIG. 36 is a view illustrating an example of an appearance of a digital still camera.

FIG. 37 is a view illustrating an example of the appearance of the digital still camera.

FIG. 38 is a view illustrating an example of an appearance of a head mounted display.

FIG. 39 is a view illustrating an example of an appearance of a see-through head mounted display.

FIG. 40 is a view illustrating an example of an appearance of a television device.

FIG. 41 is a diagram illustrating an internal configuration of a vehicle.

FIG. 42 is a diagram illustrating the internal configuration of the vehicle.

### DESCRIPTION OF EMBODIMENTS

Hereinafter, embodiments of the present disclosure will be described in detail with reference to the drawings. Note that, a light emitting element, a display device, an electronic apparatus, and the like according to the present disclosure are not limited by the embodiments. In addition, in the following embodiments, the same parts are basically denoted by the same reference signs to omit redundant description.

One or multiple embodiments (including examples and modifications) described below can each be implemented independently. On the other hand, at least some of the multiple embodiments described below may be appropriately combined with at least some of other embodiments. The multiple embodiments may include novel features different from each other. Therefore, the multiple embodiments can contribute to solving different objects or problems, and can exhibit different effects.

The present disclosure will be described according to the following order of items.
1. Embodiment
1-1. Configuration Example of Display Device
1-2. Configuration Example of Light Emitting Element
1-3. Example of Diffraction Structure of Light Emitting Element
1-4. Manufacturing Process of Display Device
1-5. Operation and Effect
2. Other Embodiments
3. Example of Resonator Structure
4. Example of Shift Structure
5. Application Example
6. Appendix

### 1. Embodiment

### <1-1. Configuration Example of Display Device>

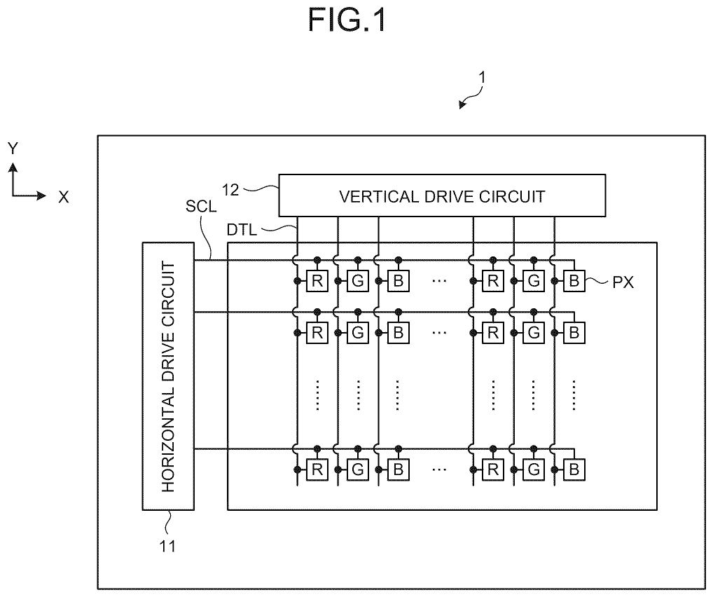

A configuration example of a display device 1 according to an embodiment will be described with reference to FIG. 1. FIG. 1 is a diagram illustrating an example of a schematic configuration of the display device 1 according to the embodiment.

As illustrated in FIG. 1, the display device 1 includes multiple light emitting elements PX arranged in a matrix, and a horizontal drive circuit 11 and a vertical drive circuit 12 for driving the light emitting elements PX. In the example of FIG. 1, a scanning line SCL is a line for scanning the light emitting elements PX, and a signal line DTL is a line for supplying various voltages to the light emitting elements PX. The display device 1 also includes a power supply line (not illustrated) that supplies a driving voltage or the like to the light emitting elements PX. Note that, in the example of FIG. 1, the horizontal drive circuit 11 and the vertical drive circuit 12 are each disposed on one end side of the display device 1, but their arrangement is not particularly limited.

For example, M light emitting elements PX are arranged in a horizontal direction (X direction in the drawing) and N light emitting elements PX are arranged in a vertical direction (Y direction in the drawing), i.e. a total of M×N light emitting elements PX are arranged in a matrix. These light emitting elements PX function as pixels of the display device 1. In the example of FIG. 1, the light emitting elements PX corresponding to red display (R: wavelength of 620 nm to 750 nm), green display (G: wavelength of 495 nm to 570 nm), and blue display (B: wavelength of 450 nm to 495 nm) are illustrated with reference signs R, G, and B, respectively. In other words, the display device 1 is a display device capable of color display.

### <1-2. Configuration Example of Light Emitting Element>

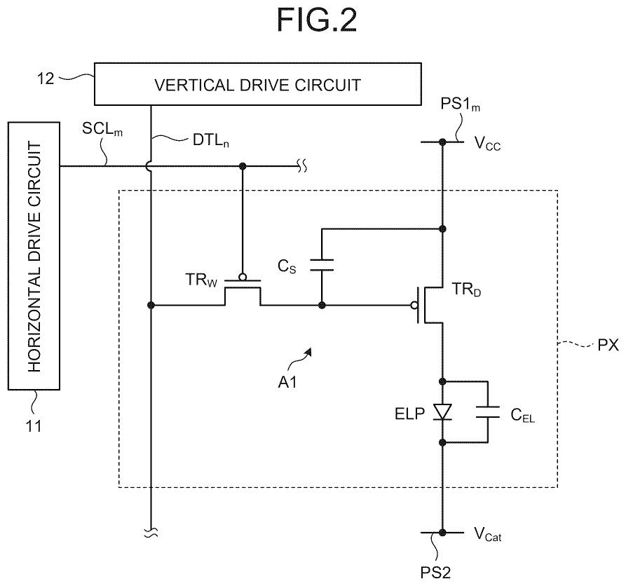

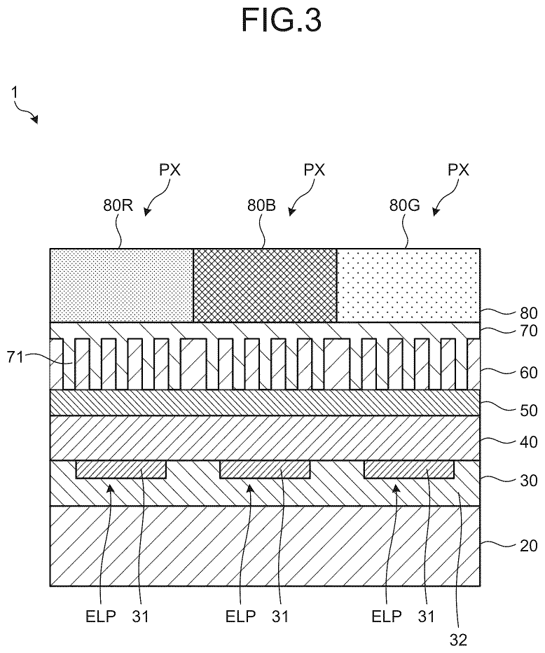

A configuration example of each light emitting element PX according to the embodiment will be described with reference to FIGS. 2 and 3. FIGS. 2 and 3 are diagrams each illustrating an example of a schematic configuration of the light emitting element PX according to the embodiment. Specifically, FIG. 2 is a circuit diagram illustrating an example of the schematic configuration of the light emitting element PX, and in the example of FIG. 2, a connection relationship observed in one light emitting element PX, more specifically, the light emitting element PX in the m-th row and the n-th column is illustrated. FIG. 3 is a cross-sectional diagram illustrating an example of the schematic configuration of the light emitting element PX.

### (Circuit Diagram)

As illustrated in FIG. 2, the light emitting element PX includes a current-driven light emitting unit ELP and a drive circuit A1 that controls light emission of the light emitting unit ELP. The drive circuit A1 includes at least a write transistor TR_{W} for writing a video signal and a drive transistor TR_{D} for applying a current to the light emitting unit ELP. These are constituted by, for example, p-channel transistors.

The drive circuit A1 further includes a capacitor C_{S}. The capacitor C_{S} is used to hold a voltage of a gate electrode applied on a source region of the drive transistor TR_{D} (so-called gate-source voltage). At the time of light emission of the light emitting element PX, one source/drain region of the drive transistor TR_{D} (the side connected to a feeder line PS1 in FIG. 2) serves as a source region, and the other source/drain region serves as a drain region.

One electrode and the other electrode constituting the capacitor C_{S} are connected to one source/drain region and a gate electrode of the drive transistor TR_{D}, respectively. The other source/drain region of the drive transistor TR_{D} is connected to an anode electrode of the light emitting unit ELP.

The light emitting element PX includes the light emitting unit ELP including an organic electroluminescence element (organic EL element). The light emitting unit ELP is a current-driven light emitting unit whose light emission luminance changes according to a value of a flowing current. For example, the light emitting unit ELP has a known configuration and structure including an anode electrode, a hole transport layer, a light emitting layer, an electron transport layer, a cathode electrode, and the like.

The other end (specifically, the cathode electrode) of the light emitting unit ELP is connected to a common feeder line PS2. A predetermined voltage V_{CATH} (for example, a ground potential) is supplied to the common feeder line PS2. Note that, the capacitance of the light emitting unit ELP is represented by a reference sign C_{EL}. In a case where a problem occurs in driving due to the small capacitance C_{EL} of the light emitting unit ELP, an auxiliary capacitance connected in parallel to the light emitting unit ELP may be provided as necessary.

The write transistor TR_{W} has a gate electrode connected to the scanning line SCL, one source/drain region connected to the signal line (data line) DTL, and the other source/drain region connected to the gate electrode of the drive transistor TR_{D}. As a result, a signal voltage from the signal line DTL is written to the capacitor C_{S} via the write transistor TR_{W}.

As described above, the capacitor C_{S} is connected between one source/drain region and the gate electrode of the drive transistor TR_{D}. A power supply voltage V_{CC} is applied from a power supply unit (not illustrated) to one source/drain region of the drive transistor TR_{D} via a feeder line PS1ₘ. When a video signal voltage V_{Sig} from the signal line DTL is written into the capacitor C_{S} via the write transistor TR_{W}, the capacitor C_{S} holds a voltage such as (V_{CC}−V_{Sig}) as a gate-to-source voltage of the drive transistor TR_{D}. A drain current Ids expressed by the following Formula (1) flows through the drive transistor TR_{D}, and the light emitting unit ELP emits light with luminance corresponding to a current value.

$${I}_{ds} = k \cdot μ \cdot {( ( {V}_{CC} - {V}_{Sig} ) - \vert {V}_{th} \vert )}^{2} \qquad ( 1 )$$

Here, μ: effective mobility, L: channel length, W: channel width, Vth: threshold voltage, Cₒₓ: (relative dielectric constant of gate insulating layer)×(dielectric constant of vacuum)/(thickness of gate insulating layer), k≡(½)·(W/L)·Cₒₓ.

### (Cross-Sectional Diagram)

As illustrated in FIG. 3, the display device 1 includes the multiple light emitting elements PX. These light emitting elements PX each include an anode layer 30, an organic layer 40, a cathode layer 50, a protective layer 60, a planarizing layer 70, and a color filter layer (CF layer) 80. The anode layer 30, the organic layer 40, the cathode layer 50, the protective layer 60, the planarizing layer 70, and the color filter layer 80 are sequentially laminated on a substrate 20 to constitute each light emitting element PX.

The substrate 20 is a support that supports the multiple light emitting elements PX arranged on one surface. Note that, although not illustrated, the substrate 20 may include, for example, a control circuit (for example, the drive circuit A1) that controls driving of each light emitting element PX, a power supply circuit that supplies power to each light emitting element PX, a multilayer wiring layer including various wiring, and the like.

The anode layer 30 is laminated on the substrate 20. The anode layer 30 includes multiple anode electrodes 31 and an insulating layer 32. Each anode electrode 31 is provided in one surface (upper surface in FIG. 3) of the insulating layer 32 for each of the light emitting elements PX. For example, the anode electrode 31 is made of a metal material, and may reflect light. The anode electrode 31 corresponds to a first electrode. The insulating layer 32 partitions off the anode electrodes 31. The insulating layer 32 may include, for example, a reflection layer and the like.

The organic layer 40 is laminated on the anode layer 30. The organic layer 40 includes at least a light emitting layer, and is formed to emit white light, for example. Note that, in the example of FIG. 3, the organic layer 40 is illustrated as one layer, but is configured by multiple layers including the light emitting layer.

The cathode layer 50 is laminated on the organic layer 40. The cathode layer 50 is formed of, for example, a material having high optical transparency and conductivity (for example, a transparent conductive material). The cathode layer 50 functions as a cathode electrode and corresponds to a second electrode.

Here, each light emitting unit ELP is configured by sequentially stacking the organic layer 40 and the cathode layer 50 on the anode electrode 31 provided for each of the light emitting elements PX. Light emitted from the organic layer 40 is emitted from the surface of the organic layer 40 on the cathode layer 50 side. In the example of FIG. 3, in the upper surface of the cathode layer 50 (or the organic layer 40), a surface opposed to the anode electrode 31 is the upper surface of the light emitting unit ELP, and the upper surface of the light emitting unit ELP serves as the light emitting surface from which the light emitting unit ELP emits light. The planar shape of the light emitting surface of the light emitting element PX generally follows the planar shape of the anode electrode 31.

In addition, the light emitting units ELP are partitioned by the insulating layer 32. In other words, the insulating layer 32 functions as a partition wall unit located between the adjacent anode electrodes 31. Note that, in the substrate 20, for example, the drive circuit A1 (see FIG. 2) is formed for each of the light emitting units ELP, and each anode electrode 31 is electrically connected to the drive circuit A1. For example, each anode electrode 31 is electrically connected to the drive circuit A1 via a conductive unit (not illustrated) such as a via provided in the insulating layer 32. The drive circuit A1 controls the light emitting state of the light emitting unit ELP according to a signal from the outside.

The protective layer 60 is laminated on the cathode layer 50. The protective layer 60 protects the inside of the display device 1 from an external environment, and prevents moisture, oxygen, and the like from penetrating the organic layer 40, for example. The protective layer 60 is made of a material having high optical transparency and high gas barrier properties, for example. As this material, for example, silicon oxide (SiOₓ), silicon nitride (SiNₓ), aluminum oxide (AlOₓ), or the like is used. In addition, the protective layer 60 may be formed as a laminated film of the above-described material or the like in order to improve the protective performance such as the gas barrier properties or to adjust the refractive index.

The planarizing layer 70 is laminated on the protective layer 60. The planarizing layer 70 flattens the protective layer 60. The planarizing layer 70 has multiple extending portions 71. These extending portions 71 extend while protruding from the planarizing layer 70 to the protective layer 60. The planarizing layer 70 and each extending portion 71 are formed of, for example, a material having high optical transparency (for example, a transparent resin material).

Here, each extending portion 71 and the protective layer 60 correspond to a diffraction layer. In this diffraction layer, two materials (a first material and a second material) having different refractive indexes and having optical transparency are arranged along the light emitting surface of the light emitting unit ELP. The planarizing layer 70 and each extending portion 71 are formed of the first material, and the protective layer 60 is formed of the second material. In other words, the first material and the second material are alternately arranged along the light emitting surface of the light emitting unit ELP.

The color filter layer 80 is laminated on the planarizing layer 70. Specifically, the color filter layer 80 includes a color filter 80R for red display, a color filter 80B for blue display, and a color filter 80G for green display. Thus, the display device 1 includes the light emitting element PX for red display, the light emitting element PX for blue display, and the light emitting element PX for green display. For example, a lens layer including multiple microlenses may be provided on the color filter layer 80.

### <1-3. Example of Diffraction Structure of Light Emitting Element>

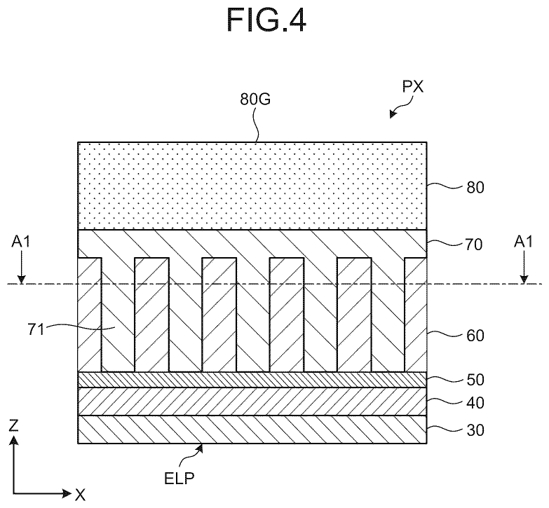

Examples 1 to 9 of the diffraction structure of the light emitting element PX according to the embodiment, that is, the diffraction layer (each extending portion 71 and the protective layer 60) will be described with reference to FIGS. 4 to 14. FIGS. 4 to 14 are diagrams each illustrating an example of a schematic configuration of the light emitting element PX according to any one of Examples 1 to 9.

### Example 1

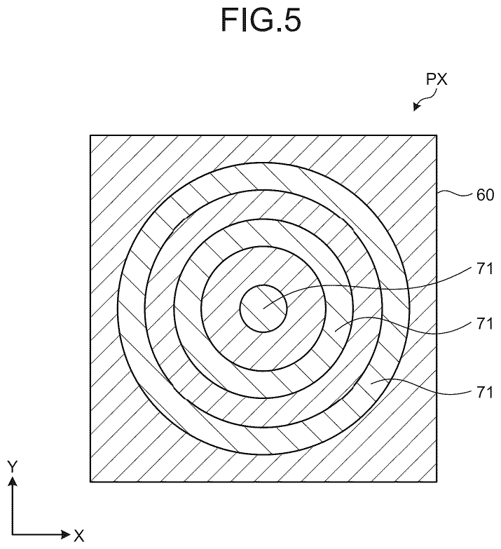

FIGS. 4 and 5 are diagrams each illustrating an example of a schematic configuration of the optical element PX according to Example 1. As illustrated in FIG. 4, each extending portion 71 extends in the height direction (vertical direction in FIG. 4) of the protective layer 60. In other words, the respective extending directions of the extending portions 71 are parallel to the height direction (thickness direction) of the protective layer 60 and perpendicular to a plane. The plane is, for example, the light emitting surface of the light emitting unit ELP. The respective lengths (extension lengths) in the height direction of the extending portions 71 are all the same as the height of the protective layer 60. These extending portions 71 are arranged at equal pitches (equal intervals) along the plane (surface extending in the left-right direction in FIG. 4).

In addition, as illustrated in FIG. 5, in a plan view, one extending portion 71 is formed in a circular shape, and the other two extending portions 71 are each formed in a cycle ring shape (circular annular shape). The plan view is, for example, a plan view parallel to the light emitting surface of the light emitting unit ELP. The circular shape extending portion 71 is disposed with its center positioned at the center of the optical element PX in a plan view. The first toric extending portion 71 is disposed with its center positioned at the center of the optical element PX in a plan view and is disposed so as to surround the circular shape extending portion 71. The second toric extending portion 71 is disposed with its center positioned at the center of the optical element PX in a plan view and is disposed so as to surround the circular shape extending portion 71 and the first toric extending portion 71. In other words, the first material for forming the extending portions 71 is arranged in a concentric circle pattern. The respective intervals of the extending portions 71 are equal.

### Example 2

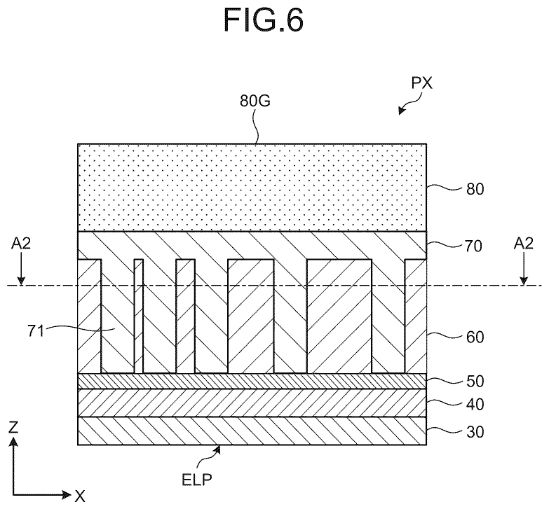

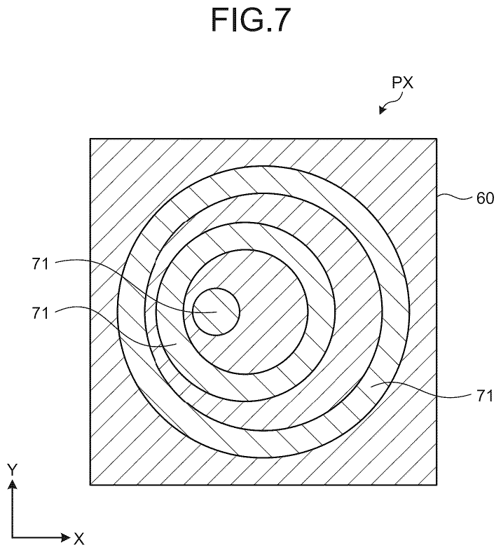

FIGS. 6 and 7 are diagrams each illustrating an example of a schematic configuration of the optical element PX according to Example 2. As illustrated in FIG. 6, each extending portion 71 extends in the height direction (vertical direction in FIG. 6) of the protective layer 60 as in Example 1. In other words, the respective extending directions of the extending portions 71 are parallel to the height direction of the protective layer 60 and perpendicular to the plane. However, in Example 2, unlike Example 1, the extending portions 71 are arranged at unequal pitches (unequal intervals) along the plane (surface extending in the left-right direction in FIG. 6).

In addition, as illustrated in FIG. 7, as in Example 1, in a plan view, one extending portion 71 is formed in a circular shape, and the other two extending portions 71 are each formed in a cycle ring shape. However, in Example 2, unlike Example 1, the circular shape extending portion 71 is disposed with its center shifted to the outer circumferential side (the left side in FIG. 7) from the center of the optical element PX in a plan view. The first toric extending portion 71 is disposed with its center shifted to the outer circumferential side (the left side in FIG. 7) of the optical element PX in a plan view and is disposed so as to surround the circular shape extending portion 71. The second toric extending portion 71 is disposed with its center positioned at the center of the optical element PX in a plan view and is disposed so as to surround the circular shape extending portion 71 and the first toric extending portion 71. In other words, the first material for forming the extending portions 71 is arranged in an eccentric circle pattern. The respective intervals of the extending portions 71 are not equal.

### Example 3

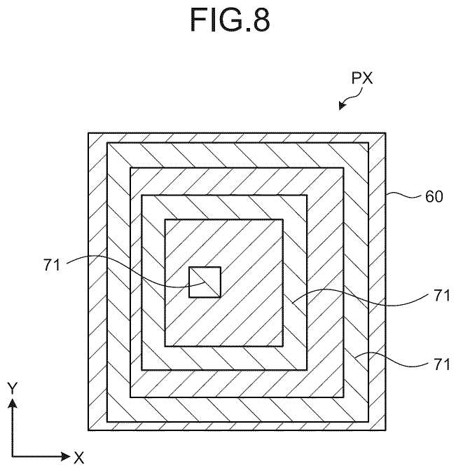

FIG. 8 is a diagram illustrating an example of a schematic configuration of the optical element PX according to Example 3. Since Example 3 is a modification of Example 2, their differences will be described. As illustrated in FIG. 8, in a plan view, one extending portion 71 is formed in a rectangular shape, and two extending portions 71 are formed in a rectangular annular shape. In the example of FIG. 8, the rectangle is a square. Note that, the annular shape is not limited to a rectangle, and may be, for example, a polygon, a triangle, or the like.

### Example 4

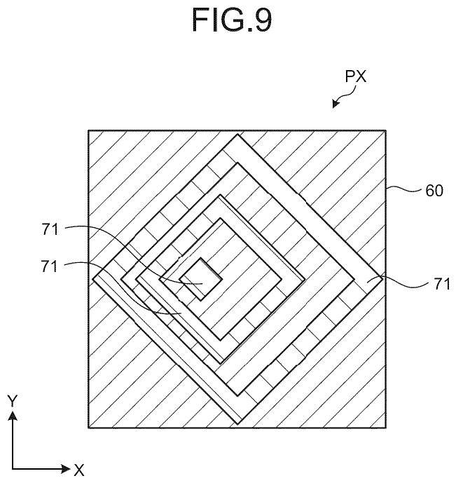

FIG. 9 is a diagram illustrating an example of a schematic configuration of the optical element PX according to Example 4. Since Example 4 is a modification of Example 3, their differences will be described. As illustrated in FIG. 9, each extending portion 71 according to Example 3 is rotated by 90 degrees and further reduced so as to fall within the size of the light emitting element PX in a plan view. One side of the annular shape extending portion 71 having a rectangular shape in a plan view is not parallel to but inclined with respect to one side of the outer shape of the light emitting element PX. In the example of FIG. 9, the inclination angle is, for example, 45 degrees, but is not limited to this.

### Example 5

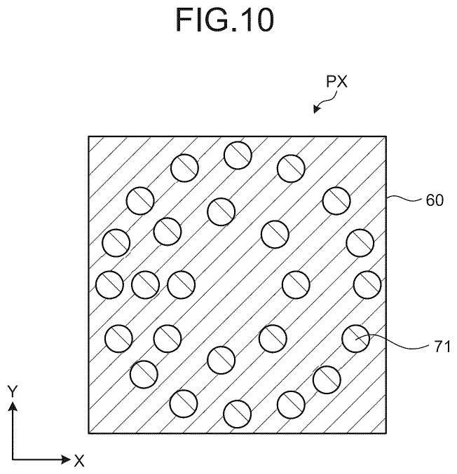

FIG. 10 is a diagram illustrating an example of a schematic configuration of the optical element PX according to Example 5. Since Example 5 is a modification of Example 2, their differences will be described. As illustrated in FIG. 10, the multiple extending portions 71 are formed in a circular shape in a plan view, and are arranged in such a way that one dot is surrounded by a double toric dot pattern. The toric dot pattern is a pattern in which dots are arranged in a cycle ring shape. Note that, the shape of each extending portion 71 is not limited to a circular shape, and may be, for example, another shape such as a rectangular shape. In addition, the annular shape is not limited to a cycle ring shape, and may be, for example, an annular shape of another shape such as a rectangular annular shape.

### Example 6

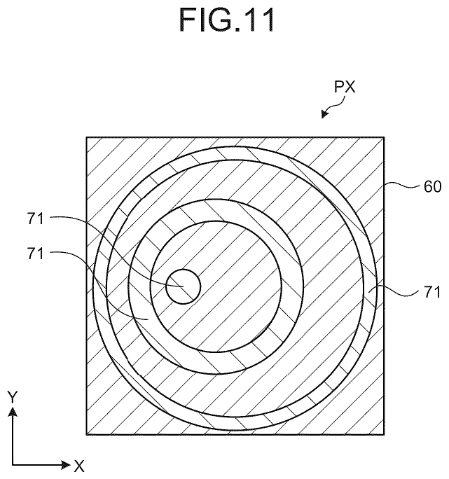

FIG. 11 is a diagram illustrating an example of a schematic configuration of the optical element PX according to Example 6. Since Example 6 is a modification of Example 2, their differences will be described. As illustrated in FIG. 11, the thicknesses of two toric extending portions 71 are different in a plan view. The thickness of the toric extending portion 71 is the thickness of the toric frame. In the example of FIG. 11, the thickness of the outer toric extending portion 71 is thinner than the thickness of the inner toric extending portion 71, but the present invention is not limited to this, and the outer toric extending portion may be conversely thicker.

### Example 7

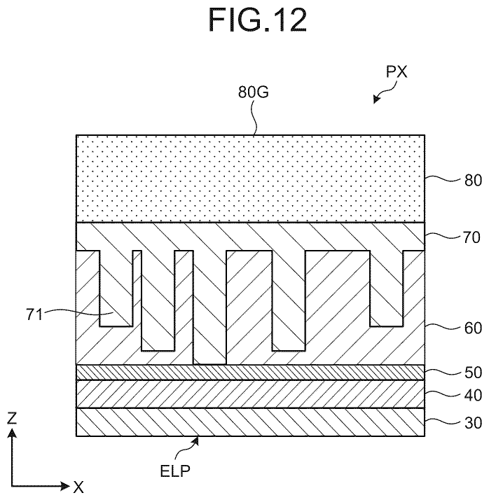

FIG. 12 is a diagram illustrating an example of a schematic configuration of the optical element PX according to Example 7. Since Example 7 is a modification of Example 2, their differences will be described. As illustrated in FIG. 12, the lengths of the extending portions 71 in the height direction are different from each other. In the example of FIG. 12, the length in the height direction of the extending portion 71 becomes shorter toward the outer circumferential side of the optical element PX, but the present invention is not limited to this, and may be conversely longer.

### Example 8

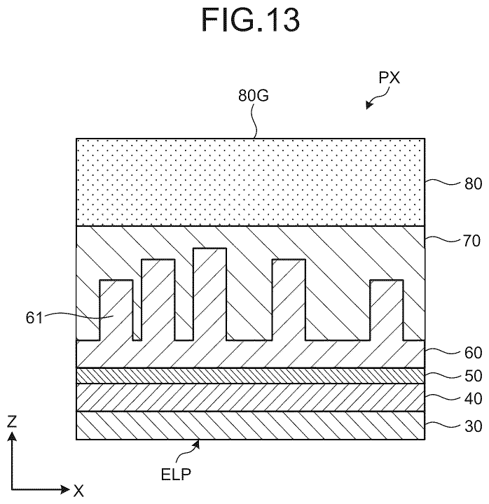

FIG. 13 is a diagram illustrating an example of a schematic configuration of the optical element PX according to Example 8. Since Example 8 is a modification of Example 2, their differences will be described. As illustrated in FIG. 13, the planarizing layer 70 does not have the extending portions 71, but the protective layer 60 has extending portions 61. The planarizing layer 70 and the extending portions 61 correspond to a diffraction layer. The function of these extending portions 61 is the same as that of the extending portions 71 of Example 2. The lengths of the extending portions 61 in the height direction are different from each other. In the example of FIG. 13, the length in the height direction of the extending portion 61 becomes shorter toward the outer circumferential side of the optical element PX, but the present invention is not limited to this, and may be conversely longer.

### Example 9

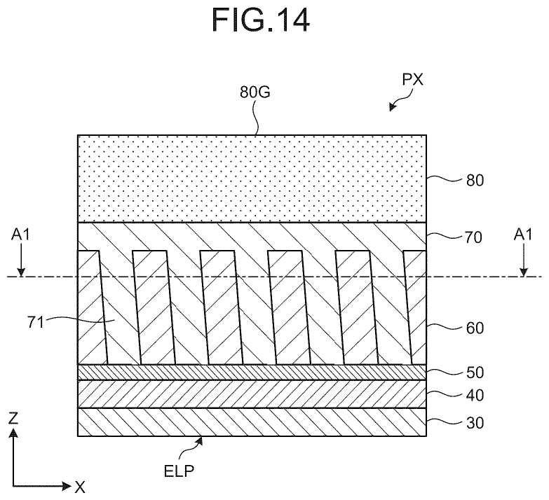

FIG. 14 is a diagram illustrating an example of a schematic configuration of the optical element PX according to Example 9. Since Example 9 is a modification of Example 1, their differences will be described. As illustrated in FIG. 14, each extending portion 71 extends in an oblique direction with respect to the height direction (vertical direction in FIG. 14) of the protective layer 60. In other words, the respective extending directions of the extending portions 71 are oblique to the height direction (thickness direction) of the protective layer 60 and inclined with respect to the plane. The inclination angle is appropriately set, and is not particularly limited.

According to the light emitting element PX of each of Examples 1 to 9 as described above, the diffraction layer (protective layer 60 and each extending portion 71, or planarizing layer 70 and each extending portion 61) is formed. The two materials constituting the diffraction layer have optical transparency, and have different refractive indexes. The light intensity, that is, total amount of light of the light emitting element PX can be increased by collection of light by the diffraction layer described above, so that a light extraction efficiency can be improved. For example, a wave guide mode can be realized by two materials having different refractive indexes. Note that, the contact region between the protective layer 60 and the planarizing layer 70 is large due to the extending portions 71 or the extending portions 61, so that the degree of adhesion between the protective layer 60 and the planarizing layer 70 can be improved.

In addition, in Example 2 and the like, the extending portions 71 are arranged at unequal pitches. The main light beam of the light emitting element PX can be controlled by changing the interval (pitch) between the extending portions 71. For example, the main light beam of the light emitting element PX can be controlled so as to be collected to the panel center side (or the panel outer circumferential side in some cases) of the display device 1. Usually, in the display device 1, viewing angle characteristics are different between a panel central portion and a panel outer circumferential portion. Thus, since the amount of light, the luminance, and the like are adjusted according to the viewing angles of the inner and outer circumferences of the panel, it is possible to suppress deterioration of the viewing angle characteristic by changing the interval between the extending portions 71 or the like. As a specific example, the light emitting element PX according to Example 1 is used in the panel central region of the display device 1, and the light emitting element PX according to Example 2 is used in the panel outer circumferential region of the display device 1. In the light emitting element PX according to Example 2, the interval between the extending portions 71 is shorter on the panel central region side (left side in FIG. 6) than on the panel outer circumferential region side (right side in FIG. 6), but may be opposite.

Note that, the configurations according to Examples 1 to 9 may be appropriately combined. In addition, in one light emitting element PX, the lengths in the height direction, the thicknesses in the planar direction, the widths in the planar direction, the shapes, and the like of the extending portions 71 or the extending portions 61 may be the same or different. By appropriately adjusting them, the light extraction efficiency can be improved and the main light beam can be reliably controlled.

Further, the extending portion 71 may be formed in the same shape as the outer shape of the anode electrode 31 in a plan view. This is because the planar shape of the light emitting surface of the light emitting unit ELP generally follows the planar shape of the anode electrode 31, and thus it is preferable to match the planar outer shape of the extending portion 71 with the planar outer shape of the anode electrode 31.

In addition, the diffraction layer including the extending portions 71 and the protective layer 60 is configured by arranging the first material and the second material having different refractive indexes and optical transparency along the light emitting surface, but is not limited to this, and may be configured by arranging three or more materials having different refractive indexes and optical transparency along the light emitting surface.

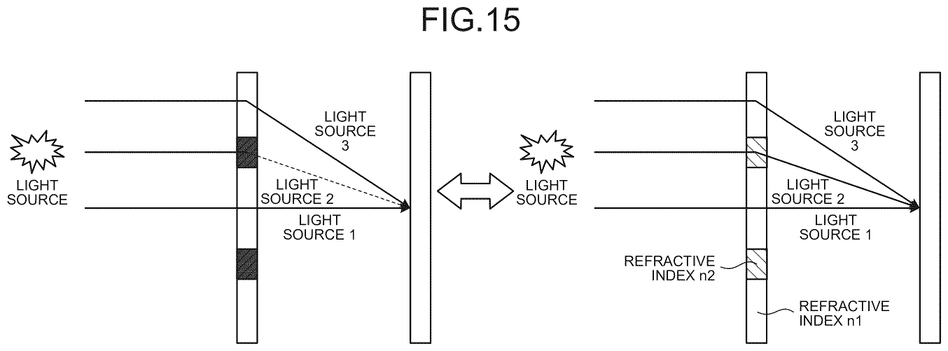

Here, FIG. 15 is a diagram for describing a difference between light diffraction by a zone plate and light diffraction by a Fresnel lens. In the example of FIG. 15, the left side illustrates the light diffraction by the zone plate, and the right side illustrates the light diffraction by the Fresnel lens.

As illustrated in FIG. 15, in the zone plate, a light path 1 (light source 1) and a light path 3 (light source 3) are mutually intensifying conditions, and the light path 1 and a light path 2 (light source 2) are mutually weakening conditions. Thus, in the zone plate, a light shielding body (black filled region in FIG. 15) is placed in the light path 2 to block the light that weakens the other (light source 2). Also in the Fresnel lens, the light path 1 (light source 1) and the light path 3 (light source 3) are mutually intensifying conditions, and the light path 1 and the light path 2 (light source 2) are mutually weakening conditions. Thus, in the Fresnel lens, a material having a refractive index of n2 (shaded region in FIG. 15) is placed in the light path 2 to change the phase of light to one for the intensifying conditions. A refractive index of a main body of the Fresnel lens is n1, and a material having a refractive index of n2 is provided for the main body. A structure similar to that of the Fresnel lens is applied to the diffraction layer of the light emitting element PX.

FIG. 16 is a diagram for describing a difference between main light beam control by the OCL step pitch and main light beam control according to Example 2. In the example of FIG. 16, the left side illustrates the main light beam control by the OCL step pitch, and the right side illustrates the main light beam control according to Example 2.

As illustrated in FIG. 16, in the main light beam control by the OCL step pitch, it is possible to offset the light beam only in the overlapping portion between the light emitting area and the OCL. However, a portion other than the overlapping portion cannot be a component of the main light beam, and the luminance decreases as compared with the case of no offset. Further, the luminance further decreases as the main light beam is offset to the high angle side. Thus, the amount by which the main light beam can be offset is also reduced. On the other hand, in the main light beam control according to Example 2, the diffractive lens structure (diffraction layer) spreads on the light emitting area, and all the components in the light emitting area can be used at the time of shifting the main light beam. Accordingly, even if the main light beam is offset to the high angle side, the luminance hardly decreases, and the amount by which the main light beam can be offset is also larger than that at the time of using the step pitch. In other words, according to Example 2, the luminance observed when the main light beam is shifted is higher than that at the time of using the step pitch, and the amount of shift of the main light beam is larger than that when at the time of using the step pitch.

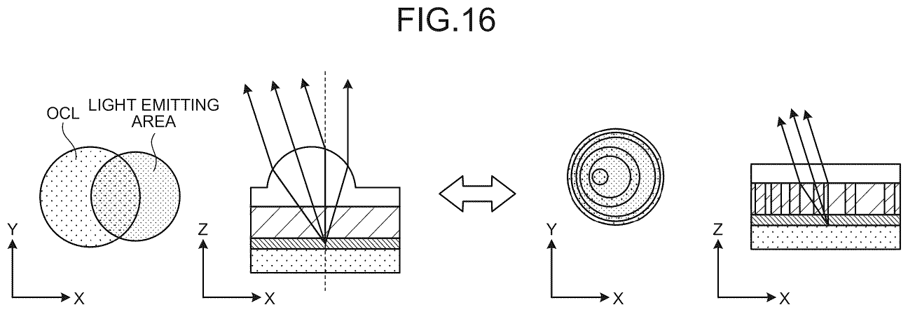

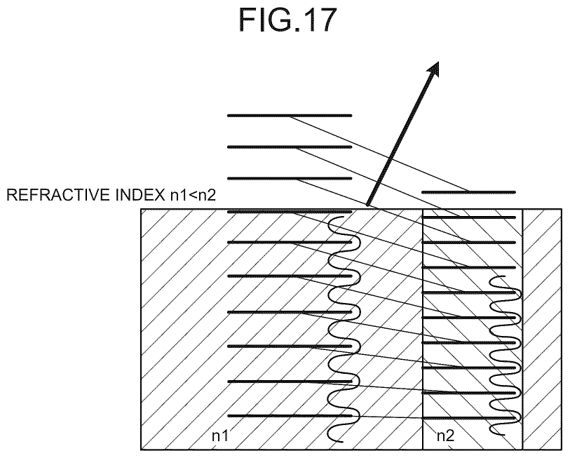

FIG. 17 is a diagram for describing a traveling direction of light passing through two media having different refractive indexes. In the example of FIG. 17, the magnitude relationship between the refractive index n1 and the refractive index n2 is n1<n2. Further, in the example of FIG. 17, multiple solid lines arranged in the vertical direction indicate peaks (or valleys) of the optical wavefront. The solid lines are parallel to each other. The speed of light in the medium is slower as the refractive index is higher, and is faster as the refractive index is lower. Thus, as illustrated in FIG. 17, when the optical wavefronts having the refractive index n1 and the refractive index n2 are connected, an optical wavefront traveling obliquely is generated as indicated by an arrow in FIG. 17. In this manner, the traveling direction of light can be controlled by appropriately selecting two media having different refractive indexes, that is, materials.

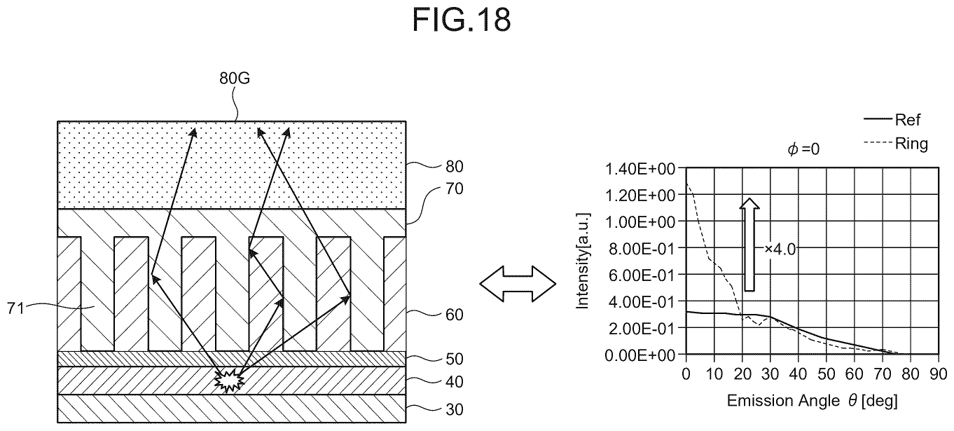

FIG. 18 is a diagram for describing the relationship between the light intensity and the radiation angle of the light emitting element. In the graph in FIG. 18, Ref (solid line) denotes a light emitting element of a comparative example in which no extending portion 71 is present, and Ring (dotted line) denotes the light emitting element PX of Example 1 in which the extending portion 71 is present (see the left diagram in FIG. 18). As illustrated in FIG. 18, the light intensity of the light emitting element PX of Example 1 is stronger in the range of the radiation angle of 0 to 20 deg than the light intensity of the light emitting element of the comparative example, and is about four times depending on the radiation angle. By providing the extending portions 71, that is, the diffraction layer in the light emitting element PX in this manner, the light intensity of the light emitting element PX can be improved.

### <1-4. Manufacturing Process of Display Device>

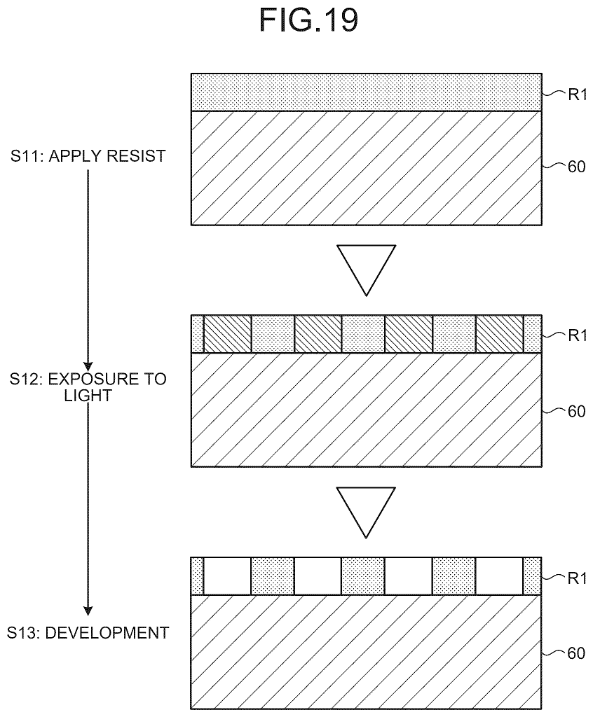

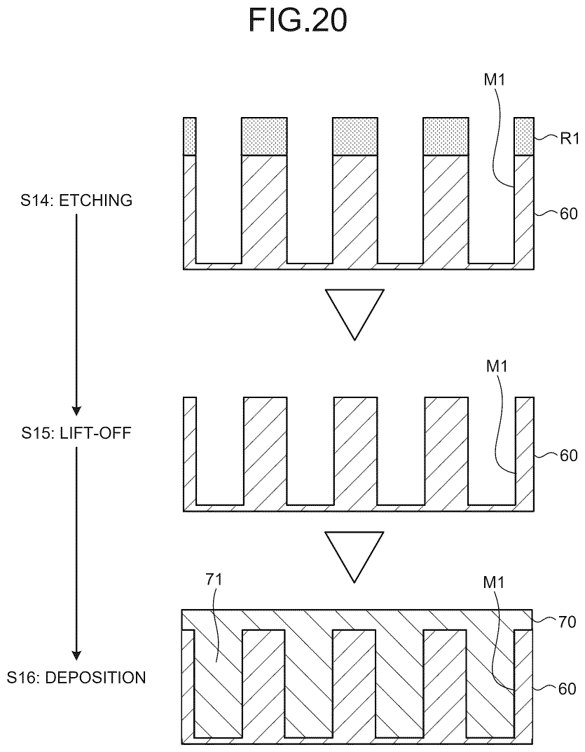

A manufacturing process of the display device 1 according to the embodiment will be described with reference to FIGS. 19 and 20. FIGS. 19 and 20 are diagrams for describing the manufacturing process of the display device 1 according to the embodiment.

First, the anode layer 30, the organic layer 40, the cathode layer 50, and the protective layer 60 are sequentially formed on the substrate 20. Next, as illustrated in FIG. 19, a resist layer R1 is formed on the protective layer 60 in Step S11 and is exposed to light in Step S12 for development in Step S13. Thus, patterning is performed. Next, as illustrated in FIG. 20, in Step S14, the patterned portion is processed by etching (for example, dry etching). As a result, multiple grooves M1 are formed in the protective layer 60. Next, in Step S15, lift-off for peeling off the resist layer R1 from the protective layer 60 is executed, and in Step S16, the planarizing layer 70 is formed on the protective layer 60 in which the grooves M1 are formed. At this time, a material for forming the planarizing layer 70 is supplied into the grooves M1, and the extending portions 71 are formed in the respective grooves M1. Then, the color filter layer 80 is formed on the planarizing layer 70.

In such a manufacturing process, after the protective layer 60 is formed, the grooves M1 are formed by etching, and the extending portions 71 are formed in the respective grooves M1 simultaneously with the formation of the planarizing layer 70. Thus, the multiple extending portions 71 protruding from the protective layer 60 can be formed in a simple process. For example, since the grooves M1 can be formed at a time, it is possible to realize a single machining process and thereby lower the difficulty of the process step. Note that, the shape of the extending portions 71 can be easily changed by changing the shape of the grooves M1, so that the extending portions 71 having various shapes can be formed easily.

Note that, in the above manufacturing process, the extending portions 71 are formed in the respective grooves M1 simultaneously with the formation of the planarizing layer 70, but the present invention is not limited to this. For example, at the time of forming the planarizing layer 70, a gas layer (for example, a layer formed of air, nitrogen, or the like) may be formed in the grooves M1 instead of providing the material for forming the planarizing layer 70 into the grooves M1. In this case, the grooves M1 (gas layer) function as the extending portions 71. The inside of the grooves M1 is filled with a gas (such as air or nitrogen). For example, by bonding the sheet-like material for forming the planarizing layer 70 on the protective layer 60, it is possible to form the gas layer in the grooves M1 without providing the material for forming the planarizing layer 70 into the grooves M1.

### <1-5. Operation and Effect>

As described above, according to the embodiment, the light emitting element PX includes the light emitting unit ELP that emits light from the light emitting surface, and the diffraction layer (for example, the protective layer 60 and the extending portions 71) that is provided on the light emitting surface side of the light emitting unit ELP and through which light emitted from the light emitting surface passes, and the diffraction layer is formed by arranging multiple materials having different refractive indexes and having optical transparency along the light emitting surface. The light intensity, that is, total amount of light of the light emitting element PX can be increased by collection of light by the diffraction layer, so that a light extraction efficiency can be improved.

Meanwhile, the multiple materials may include the first material and the second material, and the first material and the second material may be alternately arranged in the direction along the light emitting surface. As a result, the light extraction efficiency can be reliably improved.

Meanwhile, the first material and the second material may be alternately arranged at unequal pitches. Thus, the main light beam control can be realized by appropriately adjusting the unequal pitches. Note that, according to the main light beam control by the diffraction layer arranged at the unequal pitches, for example, the luminance can be improved and the amount of shift of the main light beam can be increased as compared with the OCL step pitch structure.

Meanwhile, the first material may form the multiple extending portions 71 extending in the height direction of the diffraction layer and arranged in the direction along the light emitting surface. As a result, the light extraction efficiency can be reliably improved.

Meanwhile, in a plan view parallel to the light emitting surface, one extending portion 71 of the extending portions 71 may be formed in a circular shape or a rectangular shape, and the remaining extending portions 71 may be formed in an annular shape surrounding the circular shape or rectangular shape extending portion 71. As a result, the light extraction efficiency can be reliably improved.

Meanwhile, the number of the above extending portions 71 in the annular shape may be two or more, and the respective center positions of the two or more extending portions 71 in the annular shape may be different from each other in a plan view parallel to the light emitting surface. Thus, the main light beam control can be realized by adjusting the center positions of the annular shape extending portions 71.

Meanwhile, the annular shape may be a cycle ring shape. As a result, the light extraction efficiency can be reliably improved. For example, when the planar shape of the light emitting surface, that is, the planar shape of each anode electrode 31 is a circular shape, the light extraction efficiency can be reliably improved by forming each extending portion 71 into a cycle ring shape in a plan view so as to suit the circular shape of the anode electrode.

Meanwhile, the annular shape may be a rectangular annular shape. As a result, the light extraction efficiency can be reliably improved. For example, when the planar shape of the light emitting surface, that is, the planar shape of each anode electrode 31 is a rectangular shape, the light extraction efficiency can be reliably improved by forming each extending portion 71 into a rectangular annular shape in a plan view so as to suit the rectangular shape of the anode electrode.

Meanwhile, in a plan view parallel to the light emitting surface, the extending portions 71 may be provided so as to form an annular shape dot pattern (discontinuous pattern). As a result, the light extraction efficiency can be reliably improved. For example, the dot pattern can be more finely adjusted than when the extending portions 71 are provided so as to form a continuous pattern, so that the light extraction efficiency can be reliably improved.

Meanwhile, the respective lengths in the height direction of the extending portions 71 may be the same as the height of the diffraction layer. As a result, the light extraction efficiency can be reliably improved.

Meanwhile, the respective lengths in the height direction of the extending portions 71 may be lower than the height of the diffraction layer. Thus, for example, the luminance can be adjusted by changing the respective lengths in the height direction of the extending portions 71 to adjust the phase difference, that is, the light path difference.

Meanwhile, the respective lengths in the height direction of the extending portions 71 may be different from each other. Thus, for example, the luminance can be adjusted by changing the respective lengths in the height direction of the extending portions 71 to adjust the phase difference, that is, the light path difference.

Meanwhile, the respective thicknesses of the extending portions 71 may be different from each other. Thus, for example, the luminance can be adjusted by changing the respective lengths in the height direction of the extending portions 71 to adjust the phase difference, that is, the light path difference.

Meanwhile, the respective extending directions of the extending portions 71 may be a direction perpendicular to the light emitting surface. As a result, the light extraction efficiency can be reliably improved.

Meanwhile, the respective extending directions of the extending portions 71 may be a direction inclined with respect to the light emitting surface. As a result, by appropriately adjusting the inclination angle, the light extraction efficiency can be reliably improved, and the main light beam can be reliably controlled.

Meanwhile, the light emitting unit ELP may have an electrode (for example, anode electrode 31) that reflects light. As a result, the light extraction efficiency can be reliably improved.

Meanwhile, the diffraction layer may be provided on the side opposite to the electrode in the light emitting unit ELP. As a result, the light extraction efficiency can be reliably improved.

Meanwhile, one of the multiple materials may be a gas. As a result, the light extraction efficiency can be reliably improved.

### 2. Other Embodiments

The processing according to the above embodiment (or modifications) may be performed in various different modes (modifications) other than the above embodiment. For example, the processing procedure, specific name, and information including various data and parameters illustrated in the above document and drawings can be arbitrarily changed unless otherwise specified. For example, the various types of information illustrated in the drawings are not limited to the illustrated information. In addition, the above embodiment (or modifications) can be appropriately combined within a range that does not contradict processing contents. Note that, the effects described in the present specification are merely illustrative or exemplary, and are not limited.

For example, the color filter may be configured to include fine particles constituting a coloring material and/or a quantum dot. In addition, the color filter may be configured using a known resist material to which a desired coloring material or the like is added. As the coloring material, known pigments and dyes can be used. Further, the fine particles constituting the quantum dots are not particularly limited, and for example, light emitting semiconductor nanoparticles may be used. The color filter including the coloring material performs color display by transmitting light in a target wavelength range among the light from the light emitting element PX. Meanwhile, the color filter containing fine particles constituting the quantum dot performs color display by performing wavelength conversion of the light from the light emitting element PX.

Furthermore, as the color filter array (color pattern), for example, various patterns such as a Bayer array (for example, RGBG, GRGB, RGGB, and the like), an RGB array, an RGB stripe array, and an RGB mosaic array can be used, and color filters of various complementary colors can be used in addition to color filters of RGB primary colors.

As a material constituting the optical element PX, a suitable material is appropriately selected from transparent organic materials and inorganic materials and used. The optical element PX is obtained, for example, by forming a resist on a transparent material layer and performing etching.

In addition, in the display device 1, at least one optical element (such as a microlens) may be provided so as to correspond to each light emitting element PX, or multiple optical elements may be provided so as to correspond to each light emitting element PX.

Further, as the light emitting unit ELP, an LED element, a semiconductor laser element, or the like can be used in addition to the organic electroluminescence element. These are configured using known materials and methods. From the viewpoint of configuring a planar display device, out of those elements, the light emitting unit ELP preferably has a configuration including the organic electroluminescent element.

In addition, the light emitting element PX may have a resonator structure that causes light to resonate. Since the light emitting element PX has the resonator structure, emission color of the light emitting element PX can be set to a predetermined display color, so that a color filter is basically unnecessary. However, in order to further improve the color purity of light having a long wavelength, the display device 1 may further include a color filter corresponding to the light emitting element PX for red display. Alternatively, in order to improve the color purity of the display colors in general, the display device 1 may further include a color filter corresponding to the light emitting element PX for red display, the light emitting element PX for green display, and the light emitting element PX for blue display.

Meanwhile, as a constituent material of the substrate 20, a semiconductor material, a glass material, a plastic material, or the like can be used. When the drive circuit is formed of a transistor formed on a semiconductor substrate, for example, the drive circuit may have such a configuration that a well region is provided in a semiconductor substrate made of silicon and a transistor is formed in the well. On the other hand, when the drive circuit is formed of a thin film transistor or the like, the drive circuit may be formed by forming a semiconductor thin film on a substrate made of a glass material or a plastic material. The various wiring may have known configurations and structures.

In addition, in the display device 1, a configuration of the drive circuit, which controls light emission of the light emitting element PX, or the like is not particularly limited. The configuration of the transistor constituting the drive circuit is not particularly limited, and may be, for example, a p-channel field effect transistor or an n-channel field effect transistor.

In addition, in the display device 1, the light emitting element PX is a so-called top emission type. For example, the light emitting element PX including an organic electroluminescent element is configured by sandwiching an organic layer including a hole transport layer, a light emitting layer, an electron transport layer, and the like between the first electrode and the second electrode. When a common cathode is used, the first electrode is an anode electrode, and the second electrode is a cathode electrode. The first electrode is provided on the substrate 20 for each of the light emitting elements PX.

The first electrode may be made of, for example, a simple substance or an alloy of a metal having a high work function such as platinum (Pt), gold (Au), silver (Ag), chromium (Cr), tungsten (W), nickel (Ni), copper (Cu), iron (Fe), cobalt (Co), or tantalum (Ta). In addition, the first electrode may be formed as a laminated electrode in which a transparent conductive material such as indium zinc oxide (IZO) or indium tin oxide (ITO) is laminated on a dielectric multilayer film or a thin film having high light reflectivity such as aluminum.

The second electrode may be made of, for example, a metal or an alloy having a low work function such as aluminum (Al), silver (Ag), magnesium (Mg), calcium (Ca), sodium (Na), strontium (Sr), an alloy of an alkali metal and silver, an alloy of an alkaline-earth metal and silver, an alloy of magnesium and calcium, or an alloy of aluminum and lithium. In addition, the second electrode may be made of a transparent conductive material such as indium zinc oxide (IZO) or indium tin oxide (ITO), or may be formed as a laminated electrode including a layer made of the material having a low work function described above and a layer made of a transparent conductive material such as indium zinc oxide (IZO) or indium tin oxide (ITO).

Meanwhile, the organic layer 40 is formed by laminating multiple material layers, and is provided on the entire surface including the first electrode as a common continuous film. The organic layer 40 emits light when a voltage is applied between the first electrode and the second electrode. The organic layer 40 has, for example, a structure in which a hole injection layer, a hole transport layer, a light emitting layer, an electron transport layer, and an electron injection layer are laminated in this order from the first electrode side. A hole transport material, a hole transport material, an electron transport material, and an organic light emitting material constituting the organic layer 40 are not limited, and known materials can be used.

In addition, the organic layer 40 may include a structure in which multiple light emitting layers are laminated. For example, the light emitting element PX that emits white light can be configured by laminating light emitting layers for emitting red light, blue light, and green light, or by laminating light emitting layers for emitting blue light and yellow light. In addition, a separate light emitting layer may be applied to each of the light emitting elements PX according to the color to be displayed.

Meanwhile, the pixel may include one light emitting element PX or may include multiple light emitting elements PX. For example, the pixel may include multiple sub pixels (light emitting elements PX). Specifically, one pixel can have a configuration including three types of sub pixels of a sub pixel for red display, a sub pixel for green display, and a sub pixel for blue display. Further, one pixel can use a set obtained by further adding one or multiple types of sub pixels to these three types of sub pixels (for example, a set including a sub pixel that emits white light to improve luminance, a set including a sub pixel that emits complementary color to expand a color reproduction range, a set including a sub pixel that emits yellow to expand a color reproduction range, and a set including a sub pixel that emits yellow and cyan to expand a color reproduction range).

Meanwhile, the partition wall unit defining the adjacent light emitting elements PX may be formed using a material appropriately selected from known inorganic materials and organic materials. For example, the partition wall unit may be formed by a combination of a known film forming method such as a physical vapor deposition method (PVD method) exemplified by a vacuum vapor deposition method or a sputtering method or various chemical vapor deposition methods (CVD methods) and a known patterning method such as an etching method or a lift-off method.

Meanwhile, as the value of the pixel) of the display device 1, in addition to VGA (640,480), S-VGA (800, 600), XGA (1024, 768), APRC (1152, 900), S-XGA (1280, 1024), U-XGA (1600, 1200), HD-TV (1920, 1080), and Q-XGA (2048, 1536), some image display resolutions such as (1920, 1035), (720, 480), and (1280, 960) can be exemplified, but the values are not limited to these values.

### 3. Example of Resonator Structure

The pixel that is the light emitting element PX used in the display device 1 according to the present disclosure described above may have a resonator structure that causes light generated in the light emitting unit to resonate. Hereinafter, a resonator structure applied to each embodiment will be described with reference to the drawings. Note that, any of R, G, and B may be assigned to a reference numeral as necessary for distinction (the same applies to the drawings).

### (Resonator Structure: First Example)

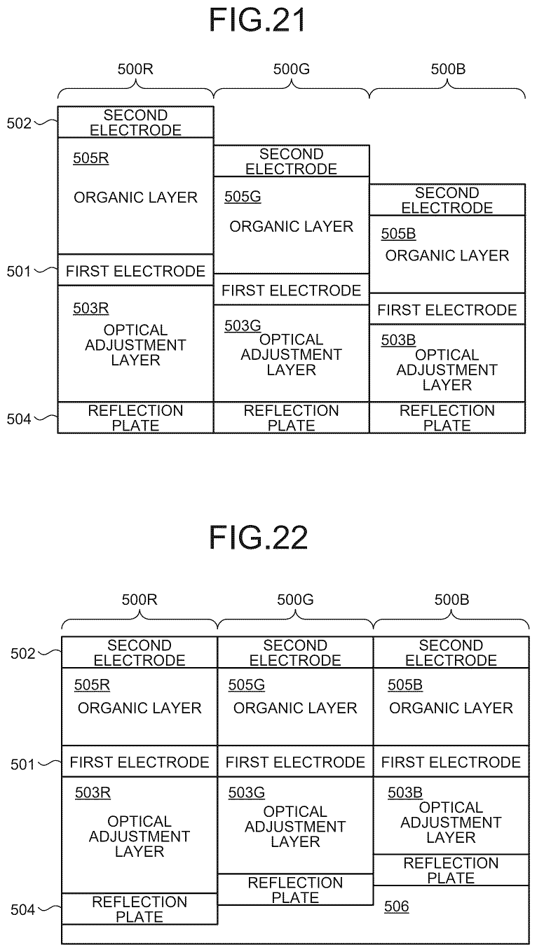

FIG. 21 is a schematic cross-sectional diagram for describing a first example of the resonator structure.

In the first example, first electrodes 501 in respective light emitting elements 500 are formed to have a common film thickness. The same applies to second electrodes 502. For example, the light emitting elements 500 correspond to the light emitting elements PX described above, the first electrodes 501 correspond to the anode electrodes 31 described above, and the second electrodes 502 correspond to the cathode layer 50 functioning as the cathode electrode described above.

A reflection plate 504 is disposed below each first electrode 501 of the light emitting element 500 with an optical adjustment layer 503 interposed between them. A resonator structure that resonates light generated by an organic layer 505 is formed between the reflection plate 504 and the second electrode 502. For example, the organic layer 505 corresponds to the above-described organic layer 40.

The reflection plates 504 in the respective light emitting elements 500 are formed to have a common film thickness. The film thickness of the optical adjustment layer 503 varies depending on the color to be displayed by the pixel. Since the optical adjustment layers 503R, 503G, and 503B have different film thicknesses, it is possible to set an optical distance at which resonance that is optimum for a wavelength of light according to the color to be displayed occurs.

In the example illustrated in FIG. 21, upper surfaces of the reflection plates 504 in light emitting elements 500R, 500G, and 500B are arranged so as to be aligned with each other. As described above, since the film thickness of the optical adjustment layer 503 varies depending on the color to be displayed by the pixel, the position of the upper surface of the second electrode 502 varies depending on the type of the light emitting element 500 (the light emitting elements 500R, 500G, and 500B).

The reflection plate 504 can be formed using, for example, a metal such as aluminum (Al), silver (Ag), or copper (Cu), or an alloy containing these as a main component.

The optical adjustment layer 503 can be made of an inorganic insulating material such as silicon nitride (SiNx), silicon oxide (SiOx), or silicon oxynitride (SiOxNy), or an organic resin material such as an acrylic resin or a polyimide resin. The optical adjustment layer 503 may be a single layer or a laminated film of multiple materials. Further, the number of laminated layers may vary depending on the type of each light emitting element 500.

The first electrode 501 can be formed using a transparent conductive material such as indium tin oxide (ITO), indium zinc oxide (IZO), or zinc oxide (ZnO).

The second electrode 502 needs to function as a semi-transmissive reflection film. The second electrode 502 can be formed using magnesium (Mg), silver (Ag), a magnesium-silver alloy (MgAg) containing these as a main component, an alloy containing an alkali metal or an alkaline earth metal, and the like.

### (Resonator Structure: Second Example)

FIG. 22 is a schematic cross-sectional diagram for describing a second example of the resonator structure.

Also in the second example, the first electrodes 501 and the second electrodes 502 in the respective light emitting elements 500 are formed to have a common film thickness.

Also in the second example, the reflection plate 504 is disposed below each first electrode 501 of the light emitting element 500 with the optical adjustment layer 503 interposed between them. A resonator structure that resonates light generated by an organic layer 505 is formed between the reflection plate 504 and the second electrode 502. As in the first example, the reflection plates 504 in the respective light emitting elements 500 are formed to have a common film thickness, and the film thickness of the optical adjustment layer 503 varies depending on the color to be displayed by the pixel.

In the first example illustrated in FIG. 21, the upper surfaces of the reflection plates 504 in the light emitting elements 500R, 500G, and 500B are arranged so as to be aligned with each other, and the position of the upper surface of the second electrode 502 varies depending on the type of the light emitting element 500.

On the other hand, in the second example illustrated in FIG. 22, the upper surfaces of the second electrodes 502 in the light emitting elements 500R, 500G, and 500B are arranged so as to be aligned with each other. In order to align the upper surfaces of the second electrodes 502, the upper surfaces of the reflection plates 504 in the light emitting elements 500R, 500G, and 500B are arranged so as to vary depending on the type of the light emitting element 500. Thus, lower surfaces of the reflection plates 504 (in other words, an upper surface of a foundation 506 illustrated in FIG. 22) have a stair shape according to the type of the light emitting element 500.

Materials and the like constituting the reflection plates 504, the optical adjustment layers 503, the first electrodes 501, and the second electrodes 502 are similar to those described in the first example, and thus their description is omitted.

### (Resonator Structure: Third Example)

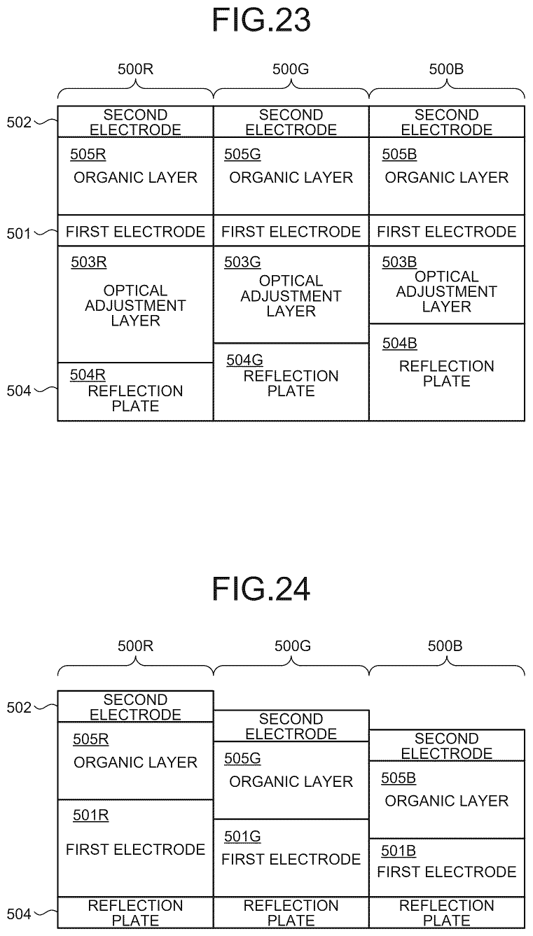

FIG. 23 is a schematic cross-sectional diagram for describing a third example of the resonator structure.

Also in the third example, the first electrodes 501 and the second electrodes 502 in the respective light emitting elements 500 are formed to have a common film thickness.

Also in the third example, the reflection plate 504 is disposed below each first electrode 501 of the light emitting element 500 with the optical adjustment layer 503 interposed between them. A resonator structure that resonates light generated by an organic layer 505 is formed between the reflection plate 504 and the second electrode 502. As in the first example and the second example, the film thickness of the optical adjustment layer 503 varies depending on the color to be displayed by the pixel. As in the second example, the upper surfaces of the second electrodes 502 in the light emitting elements 500R, 500G, and 500B are positioned so as to be aligned with each other.

In the second example illustrated in FIG. 22, in order to align the upper surfaces of the second electrodes 502, the lower surfaces of the reflection plates 504 have a stair shape according to the type of the light emitting element 500.

On the other hand, in the third example illustrated in FIG. 23, the film thickness of the reflection plate 504 is set to vary depending on the type of the light emitting element 500. More specifically, the film thickness is set so that the lower surfaces of the reflection plates 504R, 504G, and 504B are aligned with each other.

Materials and the like constituting the reflection plates 504, the optical adjustment layers 503, the first electrodes 501, and the second electrodes 502 are similar to those described in the first example, and thus their description is omitted.

### (Resonator Structure: Fourth Example)

FIG. 24 is a schematic cross-sectional diagram for describing a fourth example of the resonator structure.

In the first example illustrated in FIG. 21, the first electrodes 501 and the second electrodes 502 in the respective light emitting elements 500 are formed to have a common film thickness. The reflection plate 504 is disposed below each first electrode 501 of the light emitting element 500 with the optical adjustment layer 503 interposed between them.

On the other hand, in the fourth example illustrated in FIG. 24, the optical adjustment layer 503 is omitted, and the film thickness of the first electrode 501 is set to vary depending on the type of the light emitting element 500.

The reflection plates 504 in the respective light emitting elements 500 are formed to have a common film thickness. The film thickness of the first electrode 501 varies depending on the color to be displayed by the pixel. Since the first electrodes 501R, 501G, and 501B have different film thicknesses, it is possible to set an optical distance at which resonance that is optimum for a wavelength of light according to the color to be displayed occurs.

Materials and the like constituting the reflection plates 504, the optical adjustment layers 503, the first electrodes 501, and the second electrodes 502 are similar to those described in the first example, and thus their description is omitted.

### (Resonator Structure: Fifth Example)

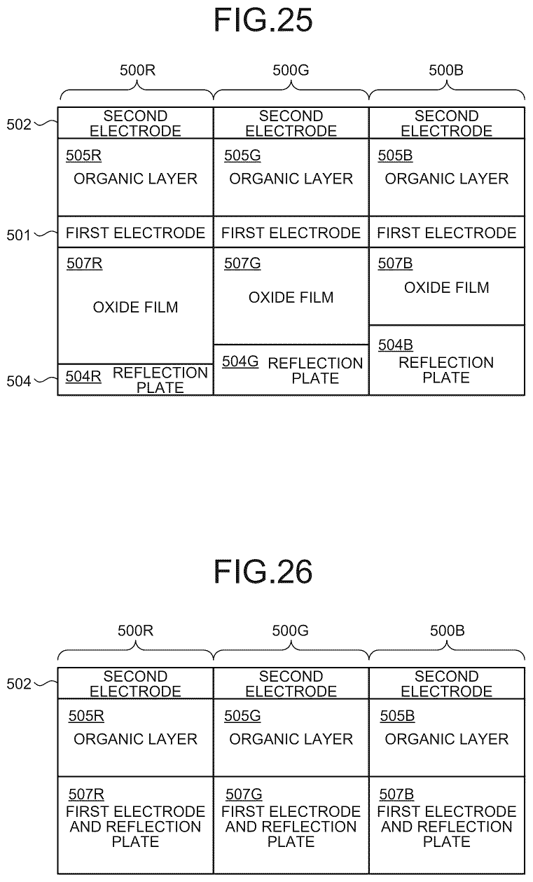

FIG. 25 is a schematic cross-sectional diagram for describing a fifth example of the resonator structure.

In the first example illustrated in FIG. 21, the first electrodes 501 and the second electrodes 502 in the respective light emitting elements 500 are formed to have a common film thickness. The reflection plate 504 is disposed below each first electrode 501 of the light emitting element 500 with the optical adjustment layer 503 interposed between them.

On the other hand, in the fifth example illustrated in FIG. 25, the optical adjustment layer 503 is omitted, and instead, an oxide film 507 is formed on the surface of each reflection plate 504. The film thickness of the oxide film 507 is set to vary depending on the type of the light emitting element 500.

The film thickness of the oxide film 507 varies depending on the color to be displayed by the pixel. Since the oxide films 507R, 507G, and 507B have different film thicknesses, it is possible to set an optical distance at which resonance that is optimum for a wavelength of light according to the color to be displayed occurs.

The oxide film 507 is a film obtained by oxidizing the surface of the reflection plate 504, and is made of, for example, aluminum oxide, tantalum oxide, titanium oxide, magnesium oxide, zirconium oxide, or the like. The oxide film 507 functions as an insulating film for adjusting a light path length (optical distance) between the reflection plate 504 and the second electrode 502.

The oxide films 507 having different film thicknesses depending on the type of the light emitting element 500 can be formed, for example, as follows.

First, an electrolytic solution is filled in a container, and a substrate on which the reflection plates 504 are formed is immersed in the electrolytic solution. Further, electrodes are disposed so as to face the reflection plates 504.

Then, a positive voltage is applied to the reflection plates 504 with the electrodes used as a reference, and the reflection plates 504 are anodized. The film thickness of the oxide film due to the anodization is proportional to the voltage value with respect to the electrode. Thus, the anodization is performed while voltages corresponding to the type of the light emitting element 500 are applied to the respective reflection plates 504R, 504G, and 504B. As a result, the oxide films 507 having different film thicknesses can be collectively formed.

Materials and the like constituting the reflection plates 504, the first electrodes 501, and the second electrodes 502 are similar to those described in the first example, and thus their description is omitted.

### (Resonator Structure: Sixth Example)

FIG. 26 is a schematic cross-sectional diagram for describing a sixth example of the resonator structure.

In the sixth example, the light emitting element 500 is configured by laminating the first electrode 501, the organic layer 505, and the second electrode 502. However, in the sixth example, the first electrode 501 is formed to function as both the electrode and the reflection plate. The first electrode (also serving as the reflection plate) 501 is made of a material having an optical constant selected according to the type of the light emitting element 500. Since the phase shift by the first electrode (also serving as the reflection plate) 501 varies, it is possible to set an optical distance at which resonance that is optimum for a wavelength of light according to the color to be displayed occurs.

The first electrode (also serving as the reflection plate) 501 can be made of a single metal such as aluminum (Al), silver (Ag), gold (Au), or copper (Cu), or an alloy containing these as a main component. For example, the first electrode (also serving as the reflection plate) 501R of the light emitting element 500R may be made of copper (Cu), and the first electrode (also serving as the reflection plate) 501G of the light emitting element 500G and the first electrode (also serving as the reflection plate) 501B of the light emitting element 500B may be made of aluminum.

Materials and the like constituting the second electrodes 502 are similar to those described in the first example, and thus their description is omitted.

### (Resonator Structure: Seventh Example)

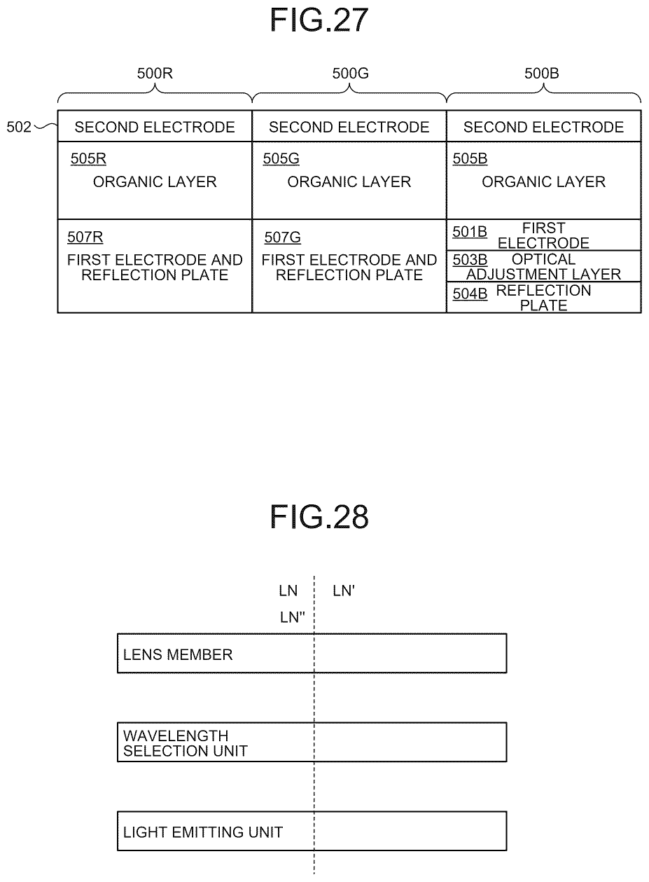

FIG. 27 is a schematic cross-sectional diagram for describing a seventh example of the resonator structure.

In the seventh example, basically, the sixth example is applied to the light emitting elements 500R and 500G, and the first example is applied to the light emitting element 500B. Also in this configuration, it is possible to set an optical distance at which resonance that is optimum for a wavelength of light according to the color to be displayed occurs.

The first electrodes (also serving as the reflection plates) 501R and 501G used in the light emitting elements 500R and 500G can be made of a single metal such as aluminum (Al), silver (Ag), gold (Au), or copper (Cu), or an alloy containing these as a main component.

Materials and the like constituting the reflection plate 504B, the optical adjustment layer 503B, and the first electrode 501B used for the light emitting element 500B are similar to those described in the first example, and thus their description is omitted.

### 4. Example of Shift Structure

The pixel that is the light emitting element PX used in the display device 1 according to the present disclosure described above may have a shift structure that shifts any one of the light emitting unit (for example, the light emitting unit ELP), a lens member (for example, the lens layer), and a wavelength selection unit (for example, the color filter layer 80). Hereinafter, the relationship among a normal line LN passing through the center of the light emitting unit, a normal line LN′ passing through the center of the lens member, and a normal line LN″ passing through the center of the wavelength selection unit will be described with reference to FIGS. 28 to 34. FIGS. 28 to 34 are conceptual diagrams for describing first to seventh examples of the shift structure, respectively.

Note that, the size of the wavelength selection unit may be appropriately changed so as to correspond to the light emitted from the light emitting element, or in a case where a light absorbing layer (black matrix layer) is provided between the wavelength selection units of the adjacent light emitting elements, the size of the light absorbing layer may be appropriately changed so as to correspond to the light emitted from the light emitting element. In addition, the size of the wavelength selection unit may be appropriately changed according to the distance (offset amount) do between the normal line passing through the center of the light emitting unit and the normal line passing through the center of the color filter layer CF. The planar shape of the wavelength selection unit may be the same as, similar to, or different from the planar shape of the lens member.

### (Shift Structure: First Example)

As illustrated in FIG. 28, the normal line LN passing through the center of the light emitting unit, the normal line LN″ passing through the center of the wavelength selection unit, and the normal line LN′ passing through the center of the lens member coincide with each other. That is, D₀=d₀=0.

### (Shift Structure: Second Example)

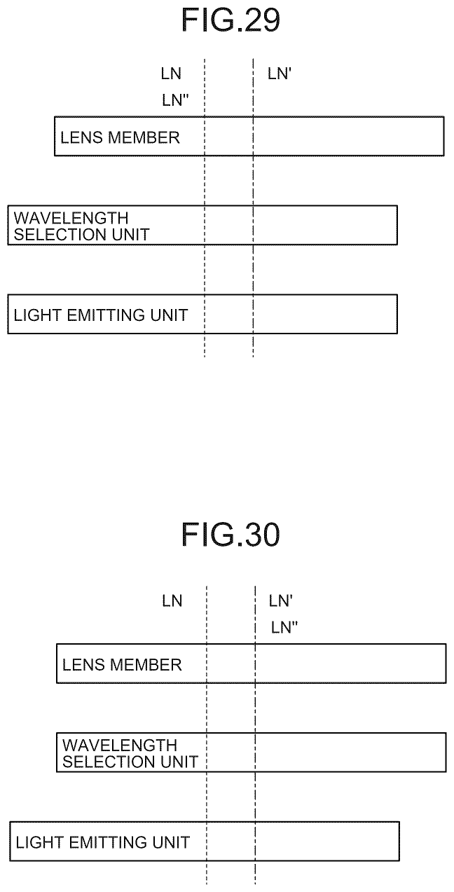

As illustrated in FIG. 29, the normal line LN passing through the center of the light emitting unit coincides with the normal line LN″ passing through the center of the wavelength selection unit, but the normal line LN passing through the center of the light emitting unit and the normal line LN″ passing through the center of the wavelength selection unit do not coincide with the normal line LN′ passing through the center of the lens member. That is, D₀≠d₀=0.

### (Shift Structure: Third Example)

As illustrated in FIG. 30, the normal line LN passing through the center of the light emitting unit does not coincide with the normal line LN″ passing through the center of the wavelength selection unit and the normal line LN′ passing through the center of the lens member, and the normal line LN″ passing through the center of the wavelength selection unit coincides with the normal line LN′ passing through the center of the lens member. That is, D₀=d₀>0.

### (Shift Structure: Fourth Example)

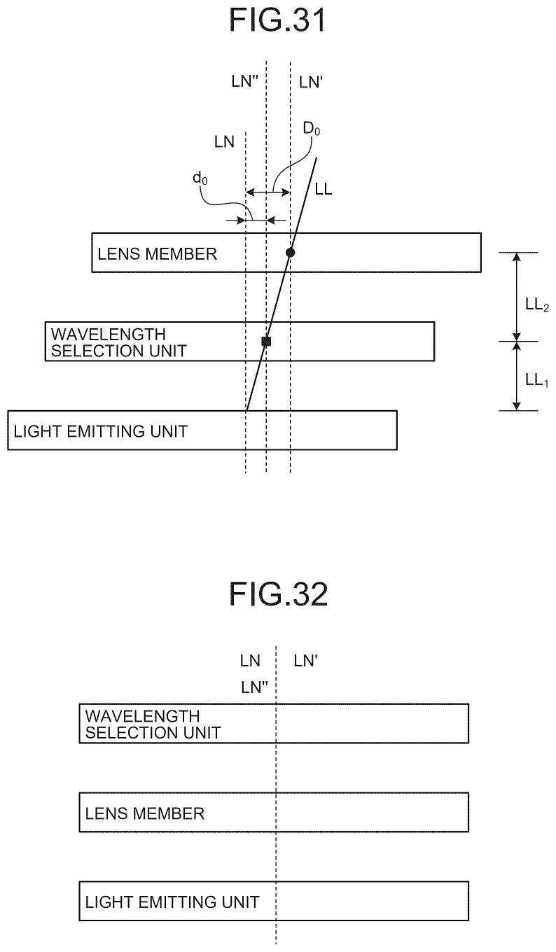

As illustrated in FIG. 31, the normal line LN passing through the center of the light emitting unit may not coincide with the normal line LN″ passing through the center of the wavelength selection unit and the normal line LN′ passing through the center of the lens member, and the normal line LN′ passing through the center of the lens member may not coincide with the normal line LN passing through the center of the light emitting unit and the normal line LN″ passing through the center of the wavelength selection unit. Here, the center of the wavelength selection unit (indicated by a black square in FIG. 31) is preferably located on a straight line LL that connects the center of the light emitting unit and the center of the lens member (indicated by a black circle in FIG. 31). Specifically, when a distance from the center of the light emitting unit to the center of the wavelength selection unit in the thickness direction is LL₁, and a distance from the center of the wavelength selection unit to the center of the lens member in the thickness direction is LL₂,

$${D}_{0} > {d}_{0} > 0$$

is satisfied, and considering manufacturing variations,
d₀:D₀=LL₁:(LL₁+LL₂) is preferably satisfied.

### (Shift Structure: Fifth Example)

As illustrated in FIG. 32, the normal line LN passing through the center of the light emitting unit, the normal line LN″ passing through the center of the wavelength selection unit, and the normal line LN′ passing through the center of the lens member coincide with each other. That is, D₀=d₀=0.

### (Shift Structure: Sixth Example)

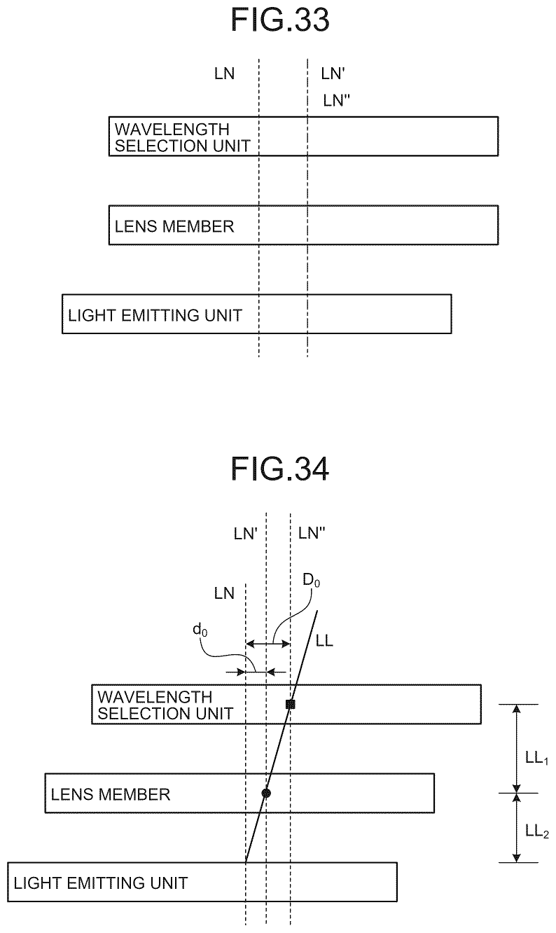

As illustrated in FIG. 33, the normal line LN passing through the center of the light emitting unit does not coincide with the normal line LN″ passing through the center of the wavelength selection unit and the normal line LN′ passing through the center of the lens member, and the normal line LN″ passing through the center of the wavelength selection unit coincides with the normal line LN′ passing through the center of the lens member. That is, D₀=d₀>0.

### (Shift Structure: Seventh Example)

As illustrated in FIG. 34, the normal line LN passing through the center of the light emitting unit may not coincide with the normal line LN″ passing through the center of the wavelength selection unit and the normal line LN′ passing through the center of the lens member, and the normal line LN′ passing through the center of the lens member may not coincide with the normal line LN passing through the center of the light emitting unit and the normal line LN″ passing through the center of the wavelength selection unit. Here, the center of the wavelength selection unit is preferably located on the straight line LL that connects the center of the light emitting unit and the center of the lens member. Specifically, when a distance from the center of the light emitting unit to the center of the wavelength selection unit in the thickness direction (indicated by a black square in FIG. 34) is LL₁, and a distance from the center of the wavelength selection unit to the center of the lens member in the thickness direction (indicated by a black circle in FIG. 34) is LL₂,

$${d}_{0} > {D}_{0} > 0$$

is satisfied, and considering manufacturing variations,
D₀:d₀=LL₂:(LL₁+LL₂) is preferably satisfied.

### 5. Application Example

The display device 1 according to the embodiment described above can be used as a display unit of an electronic apparatus in any field that displays, as an image or a video, a video signal input to the electronic apparatus or a video signal generated in the electronic apparatus. For example, the display device 1 according to the embodiment can be used as a display unit of a mobile terminal device such as a smartphone or a mobile phone, a digital still camera, a head mounted display, a see-through head mounted display, a television device, a notebook personal computer, a video camera, an electronic book, a game machine, or the like.

Note that, the display device according to the embodiment may include a module-shaped device having a sealed configuration. The display module may be provided with a circuit unit for inputting and outputting a signal and the like from the outside to a light emitting region, a flexible printed circuit (FPC), and the like.

As specific examples (application examples) of the electronic apparatus using the display device according to the embodiment, a smartphone, a digital still camera, a head mounted display, a see-through head mounted display, a television device, and a vehicle will be exemplified below. However, the specific examples exemplified here are merely an example, and the present invention is not limited to this.

### Specific Example 1

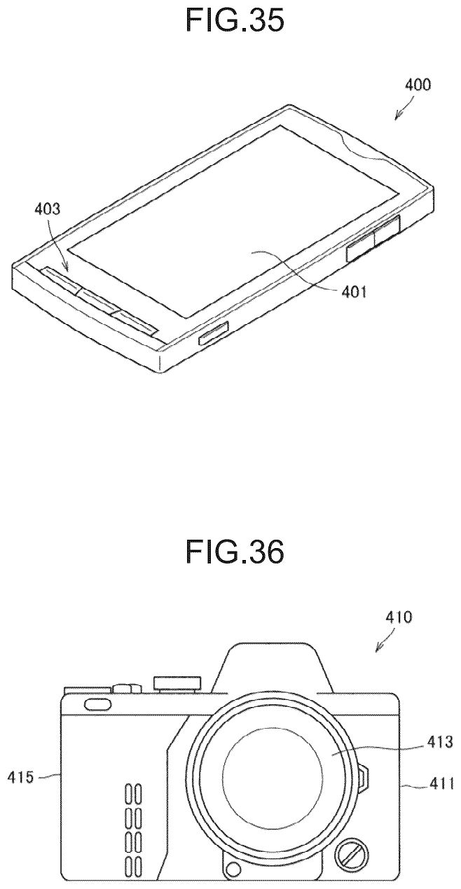

FIG. 35 is a view illustrating an example of an appearance of a smartphone 400. As illustrated in FIG. 35, the smartphone 400 includes a display unit 401 that displays various types of information, and an operation unit 403 including a button or the like that accepts an operation input by a user. The display unit 401 is configured by the display device 1 according to the present embodiment.

### Specific Example 2

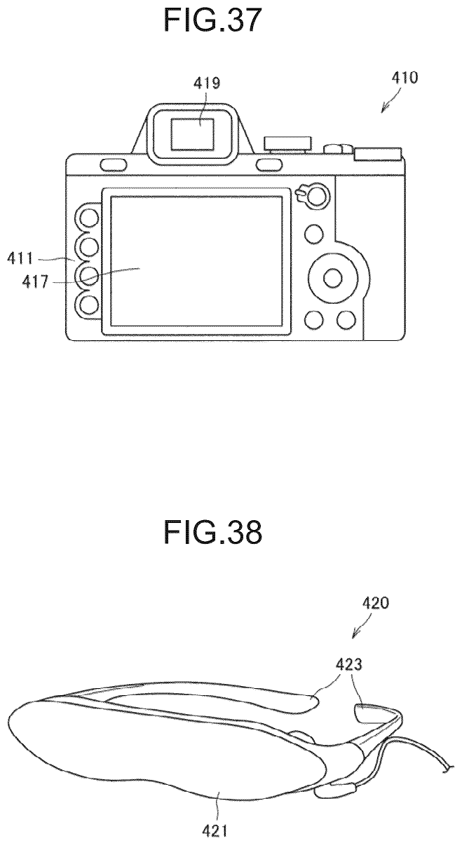

FIGS. 36 and 37 are views each illustrating an example of an appearance of a digital still camera 410. FIG. 36 is a front view of the digital still camera 410, and FIG. 37 is a rear view of the digital still camera 410. As illustrated in FIGS. 36 and 37, the digital still camera 410 is, for example, of a lens interchangeable single lens reflex type, and includes an interchangeable imaging lens unit (interchangeable lens) 413 at substantially the center of the front of a camera body portion (camera body) 411, and a grip portion 415 to be held by a photographer on the front left side.

A monitor 417 is provided at a position shifted to the left side from the center of a back surface of the camera body 411. An electronic viewfinder (eyepiece window) 419 is provided above the monitor 417. By looking into the electronic viewfinder 419, the photographer can determine the composition by visually recognizing an optical image of a subject guided from the imaging lens unit 413. Both or one of the monitor 417 and the electronic viewfinder 419 is configured by the display device 1 according to the embodiment.

### Specific Example 3

FIG. 38 is a view illustrating an example of an appearance of a head mounted display 420. As illustrated in FIG. 38, the head mounted display 420 includes, for example, ear hooking portions 423 to be worn on the user's head at both sides of a glasses-shaped display unit 421. The display unit 421 is configured by the display device 1 according to the embodiment.

### Specific Example 4

FIG. 39 is a view illustrating an example of an appearance of a see-through head mounted display 430. As illustrated in FIG. 39, the see-through head mounted display 430 includes a main body 431, an arm 433, and a lens barrel 435. The main body 431 is connected to the arm 433 and glasses 437. Specifically, an end portion of the main body 431 in the long side direction is coupled to the arm 433, and one side of a side surface of the main body 431 is coupled to the glasses 437 via a connecting member (not illustrated). Note that, the main body 431 may be directly mounted on the head of a human body.

The main body 431 incorporates a control board and a display unit for controlling the operation of the see-through head mounted display 430. The arm 433 connects the main body 431 and the lens barrel 435 to each other and supports the lens barrel 435. Specifically, the arm 433 is coupled to the end portion of the main body 431 and an end portion of the lens barrel 435, and fixes the lens barrel 435. Further, the arm 433 incorporates a signal line for communicating data related to an image provided from the main body 431 to the lens barrel 435.

The lens barrel 435 projects, through the lens of the glasses 437, image light provided from the main body 431 via the arm 433 toward the eyes of the user wearing the see-through head mounted display 430. In the see-through head mounted display 430, the display unit of the main body 431 is configured by the display device 1 according to the embodiment.

### Specific Example 5

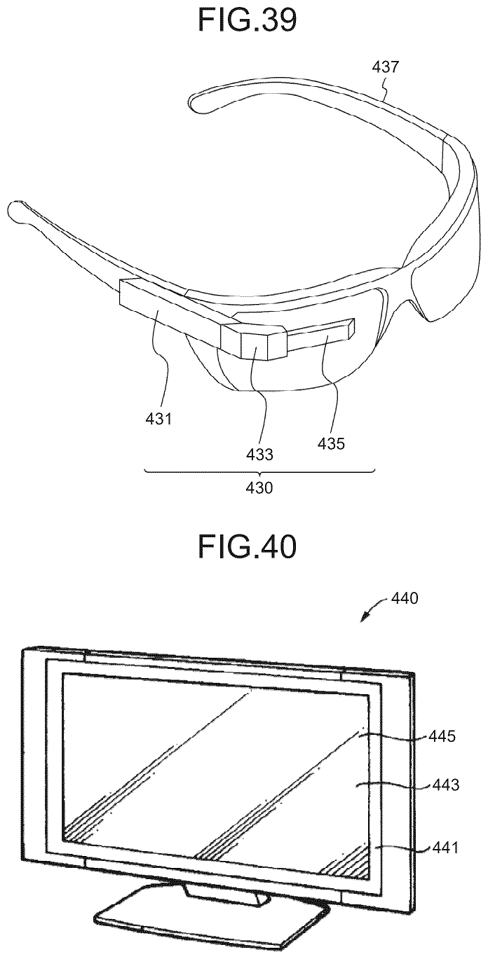

FIG. 40 is a view illustrating an example of an appearance of a television device 440. As illustrated in FIG. 40, the television device 440 includes a video display screen unit 441. The video display screen unit 441 includes, for example, a front panel 443 and a filter glass 445. The video display screen unit 441 is configured by the display device 1 according to the embodiment.

### Specific Example 6

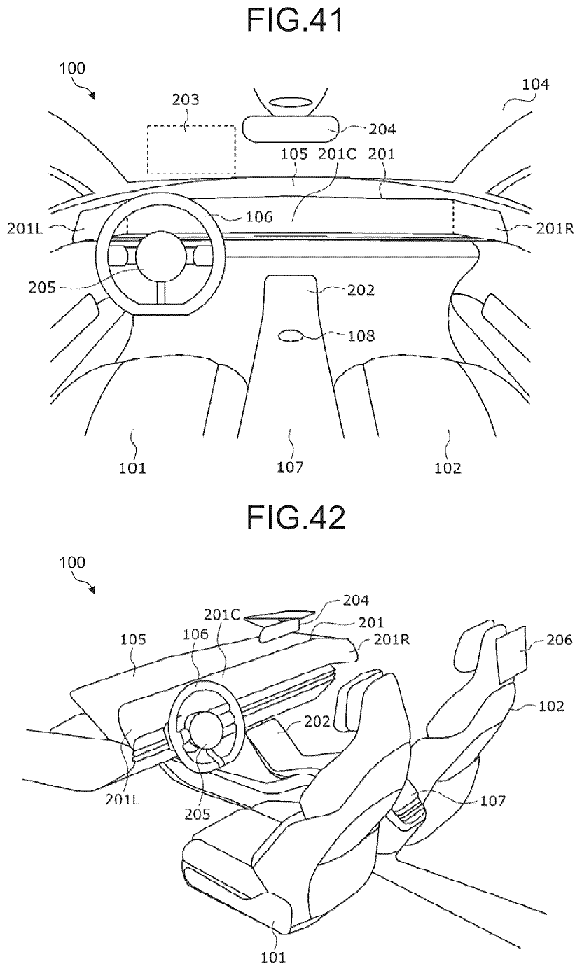

FIGS. 41 and 42 are diagrams each illustrating an internal configuration of a vehicle 100. FIG. 41 illustrates the interior of the vehicle 100 from the rear to the front of the vehicle 100, and FIG. 42 illustrates the interior of the vehicle 100 from the oblique rear to the oblique front of the vehicle 100.

As illustrated in FIGS. 41 and 42, the vehicle 100 includes a center display 201, a console display 202, a head-up display 203, a digital rear mirror 204, a steering wheel display 205, and a rear entertainment display 206. Any or all of these displays 201 to 206 are configured by the display device 1 according to the embodiment.

The center display 201 is disposed on a dashboard 105 at a position facing a driver's seat 101 and a passenger seat 102. FIGS. 41 and 42 illustrate an example of the center display 201 having a horizontally long shape extending from the driver's seat 101 side to the passenger seat 102 side, but the screen size and the arrangement location of the center display 201 are arbitrary. The center display 201 can display information detected by various sensors. As a specific example, the center display 201 can display a captured image captured by an image sensor, a distance image to an obstacle in front of or on a side of the vehicle measured by a ToF sensor, a passenger's body temperature detected by an infrared sensor, and the like. The center display 201 can be used to display, for example, at least one of safety related information, operation related information, a life log, health related information, authentication/identification related information, and entertainment related information.

The safety related information is information such as doze detection, looking-away detection, detection of mischief of a child riding together, whether or not a seat belt is fastened, and detection of leaving of an occupant, and is, for example, information detected by a sensor superimposed on the back side of the center display 201. In the operation related information, a gesture related to an operation of the occupant is detected using the sensor. The detected gesture may include operations of various kinds of equipment in the vehicle 100. For example, operations of air conditioning equipment, a navigation device, an AV device, a lighting device, and the like are detected. The life log includes life logs of all the occupants. For example, the life log includes an action record of each occupant riding in the vehicle. By acquiring and storing the life log, it is possible to check a state of the occupant at the time of an accident. In the health related information, a body temperature of the occupant is detected using a temperature sensor, and a health condition of the occupant is presumed based on the detected body temperature. Alternatively, the health condition of the occupant may be presumed by taking an image of the face of the occupant using an image sensor and presuming the health condition based on the image of the facial expression thus taken. Still alternatively, the health condition of the occupant may be presumed by communicating with the occupant in an automatic voice and presuming the health condition based on an answer of the occupant. The authentication/identification related information includes a keyless entry function of performing face authentication using a sensor, an automatic adjustment function of a sheet height and a position by face identification, and the like. The entertainment related information includes a function of detecting operation information of the AV device by the occupant using the sensor, a function of recognizing the face of the occupant by the sensor and providing content suitable for the occupant by the AV device, and the like.

The console display 202 can be used to display life log information, for example. The console display 202 is disposed near a shift lever 108 of a center console 107 between the driver's seat 101 and the passenger seat 102. The console display 202 can also display information detected by various sensors. In addition, the console display 202 may display an image of the periphery of the vehicle captured by the image sensor, or may display a distance image to an obstacle at the periphery of the vehicle.

The head-up display 203 is virtually displayed behind a windshield 104 in front of the driver's seat 101. The head-up display 203 can be used to display, for example, at least one of safety related information, operation related information, a life log, health related information, authentication/identification related information, and entertainment related information. Since the head-up display 203 is often virtually arranged in front of the driver's seat 101, it is suitable for displaying information directly related to an operation of the vehicle 100 such as the speed of the vehicle 100 and the remaining amount of fuel (battery).

The digital rear mirror 204 can not only display the rear of the vehicle 100 but also display the state of the occupant in the rear seat, and thus can be used to display the life log information, for example, by disposing the sensor so that it is superimposed on the back side of the digital rear mirror 204.

The steering wheel display 205 is disposed near the center of a steering wheel 106 of the vehicle 100. The steering wheel display 205 can be used to display, for example, at least one of safety related information, operation related information, a life log, health related information, authentication/identification related information, and entertainment related information. In particular, since the steering wheel display 205 is located close to the driver's hand, it is suitable for displaying life log information such as the body temperature of the driver, or for displaying information related to the operation of an AV device, an air conditioning unit, and the like.

The rear entertainment display 206 is mounted on the back side of the driver's seat 101 and the passenger seat 102, and is for viewing by the occupant in the rear seat. The rear entertainment display 206 can be used to display, for example, at least one of safety related information, operation related information, a life log, health related information, authentication/identification related information, and entertainment related information. In particular, since the rear entertainment display 206 is located in front of the occupant in the rear seat, information related to the occupant in the back seat is displayed. For example, information related to the operation of the AV device and the air conditioning unit may be displayed, or a result of measuring the body temperature and the like of the occupant in the rear seat by the temperature sensor may be displayed.

As described above, by disposing the sensor so that it is superimposed on the back side of the display, a distance to an object existing in the surroundings can be measured. Optical distance measurement methods are roughly classified into a passive type and an active type. The passive type measures a distance by receiving light from an object without projecting light from the sensor to the object. Examples of the passive type include a lens focus method, a stereo method, and a monocular vision method. The active type measures a distance by projecting light to an object and receiving light from the object by the sensor. Examples of the active type include an optical radar method, an active stereo method, an illuminance difference stereo method, a moiré topography method, and an interference method. The display device 1 according to the embodiment can be applied to any of these types of distance measurement. By using the sensor disposed to be superimposed on the back side of the display device 1 according to the embodiment, the above-described passive or active distance measurement can be performed.

Note that, the electronic apparatus to which the display device 1 according to each embodiment can be applied is not limited to the above examples. The display device 1 according to each embodiment can be applied to a display unit of an electronic apparatus in any field that performs display on the basis of an image signal input from the outside or an image signal generated inside. In other words, the technology according to the present disclosure can be applied to various products. For example, as the vehicle 100 described above, the display device 1 according to each embodiment may be realized as a display unit of any type of mobile body such as an automobile, an electric vehicle, a hybrid electric vehicle, a motorcycle, a bicycle, a personal mobility, an airplane, a drone, a ship, a robot, a construction machine, and an agricultural machine (tractor). Further, for example, the display device 1 according to each embodiment may be applied to a display unit included in an endoscopic surgery system, a microscopic surgery system, or the like.

Although the embodiments, the modifications, the application examples, and the like of the present disclosure have been described in detail with reference to the accompanying drawings, the technical scope of the present disclosure is not limited to such examples. It is obvious that a person having ordinary knowledge in the technical field of the present disclosure can conceive of various changes or modifications within the scope of the technical idea described in the claims, and it is naturally understood that these also belong to the technical scope of the present disclosure.

### 6. Appendix

Note that, the present technique can also have the following configuration.

(1)

A light emitting element comprising:
a light emitting unit that emits light from a light emitting surface; and
a diffraction layer that is provided on the light emitting surface side of the light emitting unit and through which the light emitted from the light emitting surface passes, wherein
the diffraction layer is formed by arranging a plurality of materials having different refractive indexes and having optical transparency along the light emitting surface.
   (2)

The light emitting element according to (1), wherein
the plurality of materials include a first material and a second material, and
the first material and the second material are alternately arranged in a direction along the light emitting surface.
   (3)

The light emitting element according to (2), wherein
the first material and the second material are alternately arranged at unequal pitches.
   (4)

The light emitting element according to (2) or (3), wherein
the first material forms a plurality of extending portions extending in a height direction of the diffraction layer and arranged in the direction along the light emitting surface.
   (5)

The light emitting element according to (4), wherein
in a plan view parallel to the light emitting surface, one of the plurality of extending portions is formed in a circular shape or a rectangular shape, and the remaining extending portions are formed in an annular shape surrounding the circular shape or rectangular shape extending portion.
   (6)

The light emitting element according to (5), wherein
the number of the extending portions in the annular shape is two or more, and
the respective center positions of the two or more extending portions in the annular shape are different from each other in the plan view parallel to the light emitting surface.
   (7)

The light emitting element according to (5), wherein
the annular shape is a cycle ring shape.
   (8)

The light emitting element according to (5), wherein
the annular shape is a rectangular annular shape.
   (9)

The light emitting element according to (4), wherein,
in a plan view parallel to the light emitting surface, the plurality of extending portions are provided so as to form an annular shape dot pattern.
   (10)

The light emitting element according to any one of (4) to (9), wherein
respective lengths in the height direction of the plurality of extending portions are the same as a height of the diffraction layer.
   (11)

The light emitting element according to any one of (4) to (9), wherein
respective lengths in the height direction of the plurality of extending portions are lower than a height of the diffraction layer.
   (12)

The light emitting element according to any one of (4) to (9), wherein
respective lengths in the height direction of the plurality of extending portions are different from each other.
   (13)

The light emitting element according to any one of (4) to (12), wherein
respective thicknesses of the plurality of extending portions are different from each other.
   (14)

The light emitting element according to any one of (4) to (13), wherein
respective extending directions of the plurality of extending portions are a direction perpendicular to the light emitting surface.
   (15)

The light emitting element according to any one of (4) to (13), wherein
respective extending directions of the plurality of extending portions are a direction inclined with respect to the light emitting surface.
   (16)

The light emitting element according to any one of (1) to (15), wherein
the light emitting unit has an electrode that reflects light.
   (17)

The light emitting element according to (16), wherein
the diffraction layer is provided on a side opposite to the electrode in the light emitting unit.
   (18)

The light emitting element according to any one of (1) to (17), wherein
one of the plurality of materials is a gas.
   (19)

A display device comprising
a plurality of light emitting elements, wherein
the plurality of light emitting elements each include:
a light emitting unit that emits light from a light emitting surface; and
a diffraction layer that is provided on the light emitting surface side of the light emitting unit and through which the light emitted from the light emitting surface passes, and
the diffraction layer is formed by arranging a plurality of materials having different refractive indexes and having optical transparency along the light emitting surface.
   (20)

An electronic apparatus comprising
a display device that includes a plurality of light emitting elements, wherein
the plurality of light emitting elements each include:
a light emitting unit that emits light from a light emitting surface; and
a diffraction layer that is provided on the light emitting surface side of the light emitting unit and through which the light emitted from the light emitting surface passes, and
the diffraction layer is formed by arranging a plurality of materials having different refractive indexes and having optical transparency along the light emitting surface.
   (21)

A display device including multiple light emitting elements according to any one of (1) to (18).

(22)

An electronic apparatus including a display device including multiple light emitting elements according to any one of (1) to (18).

### REFERENCE SIGNS LIST

1 DISPLAY DEVICE
11 HORIZONTAL DRIVE CIRCUIT
12 VERTICAL DRIVE CIRCUIT
20 SUBSTRATE
30 ANODE LAYER
31 ANODE ELECTRODE
32 INSULATING LAYER
40 ORGANIC LAYER
50 CATHODE LAYER
60 PROTECTIVE LAYER
70 PLANARIZING LAYER
71 EXTENDING PORTION
80 COLOR FILTER LAYER
80R COLOR FILTER
80B COLOR FILTER
80G COLOR FILTER
A1 DRIVE CIRCUIT
DTL SIGNAL LINE
ELP LIGHT EMITTING UNIT
M1 GROOVE
PS1 FEEDER LINE
PS2 COMMON FEEDER LINE
PX LIGHT EMITTING ELEMENT
R1 RESIST LAYER
SCL SCANNING LINE
TR_{D} DRIVE TRANSISTOR
TR_{W} WRITE TRANSISTOR

1. A light emitting element comprising:
a light emitting unit that emits light from a light emitting surface; and
a diffraction layer that is provided on the light emitting surface side of the light emitting unit and through which the light emitted from the light emitting surface passes, wherein
the diffraction layer is formed by arranging a plurality of materials having different refractive indexes and having optical transparency along the light emitting surface.

2. The light emitting element according to claim 1, wherein
the plurality of materials include a first material and a second material, and
the first material and the second material are alternately arranged in a direction along the light emitting surface.

3. The light emitting element according to claim 2, wherein
the first material and the second material are alternately arranged at unequal pitches.

4. The light emitting element according to claim 2, wherein
the first material forms a plurality of extending portions extending in a height direction of the diffraction layer and arranged in the direction along the light emitting surface.

5. The light emitting element according to claim 4, wherein
in a plan view parallel to the light emitting surface, one of the plurality of extending portions is formed in a circular shape or a rectangular shape, and the remaining extending portions are formed in an annular shape surrounding the circular shape or rectangular shape extending portion.

6. The light emitting element according to claim 5, wherein
the number of the extending portions in the annular shape is two or more, and
the respective center positions of the two or more extending portions in the annular shape are different from each other in the plan view parallel to the light emitting surface.

7. The light emitting element according to claim 5, wherein
the annular shape is a cycle ring shape.

8. The light emitting element according to claim 5, wherein
the annular shape is a rectangular annular shape.

9. The light emitting element according to claim 4, wherein,
in a plan view parallel to the light emitting surface, the plurality of extending portions are provided so as to form an annular shape dot pattern.

10. The light emitting element according to claim 4, wherein
respective lengths in the height direction of the plurality of extending portions are the same as a height of the diffraction layer.

11. The light emitting element according to claim 4, wherein
respective lengths in the height direction of the plurality of extending portions are lower than a height of the diffraction layer.

12. The light emitting element according to claim 4, wherein
respective lengths in the height direction of the plurality of extending portions are different from each other.

13. The light emitting element according to claim 4, wherein
respective thicknesses of the plurality of extending portions are different from each other.

14. The light emitting element according to claim 4, wherein
respective extending directions of the plurality of extending portions are a direction perpendicular to the light emitting surface.

15. The light emitting element according to claim 4, wherein
respective extending directions of the plurality of extending portions are a direction inclined with respect to the light emitting surface.

16. The light emitting element according to claim 1, wherein
the light emitting unit has an electrode that reflects light.

17. The light emitting element according to claim 16, wherein
the diffraction layer is provided on a side opposite to the electrode in the light emitting unit.

18. The light emitting element according to claim 1, wherein
one of the plurality of materials is a gas.

19. A display device comprising
a plurality of light emitting elements, wherein
the plurality of light emitting elements each include:
a light emitting unit that emits light from a light emitting surface; and
a diffraction layer that is provided on the light emitting surface side of the light emitting unit and through which the light emitted from the light emitting surface passes, and
the diffraction layer is formed by arranging a plurality of materials having different refractive indexes and having optical transparency along the light emitting surface.

20. An electronic apparatus comprising
a display device that includes a plurality of light emitting elements, wherein
the plurality of light emitting elements each include:
a light emitting unit that emits light from a light emitting surface; and
a diffraction layer that is provided on the light emitting surface side of the light emitting unit and through which the light emitted from the light emitting surface passes, and
the diffraction layer is formed by arranging a plurality of materials having different refractive indexes and having optical transparency along the light emitting surface.
